(19) United States
(12) Patent Application Publication
(10) Pub. No.: US 2026/0206227 A1
(43) Pub. Date: Jul. 16, 2026

(54) MEMORY DEVICE INCLUDING SPLIT MEMORY CELLS

(71) Applicant: Micron Technology, Inc., Boise, ID (US)

(72) Inventors: Nicolo' Gravellini, Milano (IT); Lorenzo Pedrazzetti, Soncino (IT); Paolo Tessariol, Arcore (IT)

(21) Appl. No.: 19/022,632

(22) Filed: Jan. 15, 2025

(51) Int. Cl. H10B 43/35; H10B 43/10; H10B 43/27

(52) U.S. Cl. CPC H10B 43/35; H10B 43/10; H10B 43/27

(57) ABSTRACT

Some embodiments include apparatuses and methods of forming the apparatuses. One of the apparatuses includes a memory device. The memory device includes levels of conductive materials interleaved with levels of dielectric materials and a memory cell pillar extending through the levels of conductive materials and the levels of dielectric materials. The memory cell pillar includes: a first dielectric material; a second dielectric material; a memory storage material between the first dielectric material and the second dielectric material; a semiconductor material adjacent the second dielectric material; a recess between a portion of the first dielectric material, a portion of the second dielectric material, and a portion of the memory storage material; and a third dielectric material filled in the recess.

### BACKGROUND

A memory device (e.g., a flash memory device) has memory cells for storing information. In some conventional memory devices, to increase cell density, the memory cells are stacked one over another and form respective memory cell pillars. However, for some conventional techniques, it can be a challenge to form such memory cell pillars at a relatively low cost.

### BRIEF DESCRIPTION OF THE DRAWINGS

FIG. 1 shows a block diagram of an apparatus in the form of a memory device, according to some embodiments described herein.

FIG. 2 shows a general schematic diagram of a portion of a memory device including a memory array having blocks (blocks of memory cells), according to some embodiments described herein.

FIG. 3A shows a detailed schematic diagram of two blocks of the memory device of FIG. 2, according to some embodiments described herein.

FIG. 3B shows an example of the memory device of FIG. 3A including multiple drain select gates, according to some embodiments described herein.

FIG. 4 shows a top view of a structure of a portion of the memory device of FIG. 3A including a region of a memory array, data lines extending among the blocks of the memory device, and dielectric structures between the blocks, according to some embodiments described herein.

FIG. 5A shows a side view (e.g., cross-section) of a structure of a portion of the memory device of FIG. 4, including tiers of materials that include respective memory cells associated with memory cell pillars and control gates, according to some embodiments described herein.

FIG. 5B and FIG. 5C show top views of different control gates and associated memory cells of FIG. 5A, according to some embodiments described herein.

FIG. 6 shows top views of a portion of the structure of the memory device of FIG. 4, according to some embodiments described herein.

FIG. 7A shows a top view of a portion of the memory device of FIG. 6 including details of some of the memory cell pillars of the memory device, according to some embodiments described herein.

FIG. 7B shows details of a pair of memory cell pillars of FIG. 7A, according to some embodiments described herein.

FIG. 7C shows a perspective view of a pair of memory cell pillars of the memory device of FIG. 7A, according to some embodiments described herein.

FIG. 8 shows a variation of the memory device of FIG. 6, according to some embodiments described herein.

FIG. 9A through FIG. 26B show different views of elements during processes of forming a memory device including forming conductive contacts of the memory device, according to some embodiments described herein.

### DETAILED DESCRIPTION

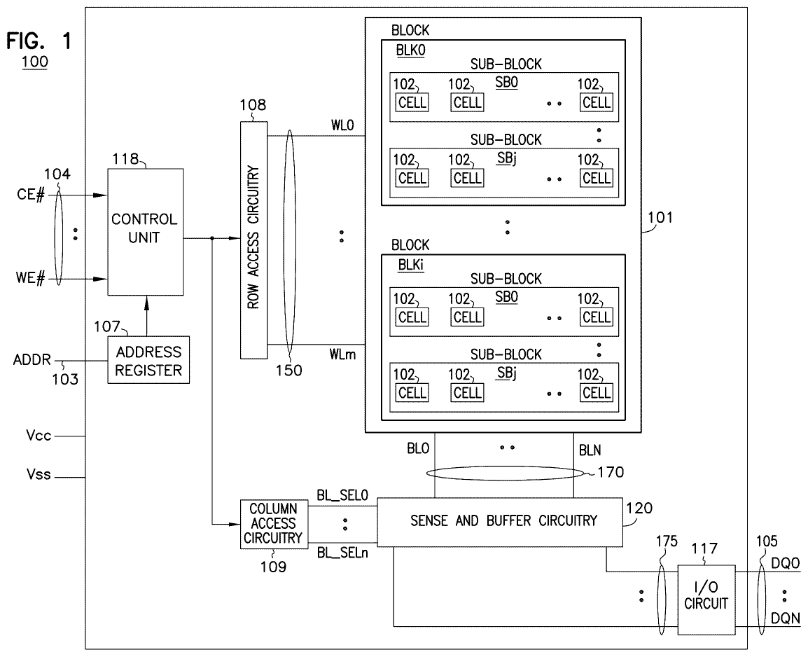

The techniques described herein involve a memory device including memory cell pillars and dielectric structures between adjacent memory cell pillars. The memory cell pillars are arranged in pairs. Each pair of memory cell pillars is separated (split) from each other by a respective dielectric structure. The pairs of memory cell pillars can be arranged in rows. The dielectric structures within a row are separated from each other. The techniques described herein also include processes for forming the memory cell pillars. The structure of the memory device and processes described herein can improve cell density, cost, and reliability and performance of the memory device. Other improvements and benefits of the techniques described herein are further discussed below with reference to FIG. 1 through FIG. 26B.

FIG. 1 shows a block diagram of an apparatus in the form of a memory device 100, according to some embodiments described herein. Memory device 100 can include a memory array (or multiple memory arrays) 101 containing memory cells 102 arranged in blocks (blocks of memory cells), such as blocks BLK0 through BLKi. Each of blocks BLK0 through BLKi can include its own sub-blocks, such as sub-blocks SB0 through SBj. A sub-block is a portion of a block. In the physical structure of memory device 100, memory cells 102 can be arranged vertically (e.g., stacked one over another) over a substrate (e.g., a semiconductor substrate) of memory device 100.

As shown in FIG. 1, memory device 100 can include access lines (which can include word lines) 150 and data lines (which can include bit lines) 170. Access lines 150 can carry signals (e.g., word line signals) WL0 through WLm. Data lines 170 can carry signals (e.g., bit line signals) BL0 through BLn. Memory device 100 can use access lines 150 to selectively access memory cells 102 of blocks BLK0 through BLKi and data lines 170 to selectively exchange information (e.g., data) with memory cells 102 of blocks BLK0 through BLKi. Data lines 170 can be shared among blocks BLK0 through BLKi.

Memory device 100 can include an address register 107 to receive address information (e.g., address signals) ADDR on lines (e.g., address lines) 103. Memory device 100 can include row access circuitry 108 and column access circuitry 109 that can decode address information from address register 107. Based on decoded address information, memory device 100 can determine which memory cells 102 of which sub-blocks of blocks BLK0 through BLKi are to be accessed during a memory operation. Memory device 100 can perform a read operation to read (e.g., sense) information (e.g., previously stored information) from memory cells 102 of blocks BLK0 through BLKi, or a write (e.g., programming) operation to store (e.g., program) information in memory cells 102 of blocks BLK0 through BLKi. Memory device 100 can use data lines 170 associated with signals BL0 through BLn to provide information to be stored in memory cells 102 or obtain information read (e.g., sensed) from memory cells 102. Memory device 100 can also perform an erase operation to erase information from some or all of memory cells 102 of blocks BLK0 through BLKi.

Memory device 100 can include a control unit 118 that can be configured to control memory operations of memory device 100 based on control signals on lines 104. Examples of the control signals on lines 104 include one or more clock signals and other signals (e.g., a chip enable signal CE#, a write enable signal WE#) to indicate which operation (e.g., read, write, or erase operation) memory device 100 can perform. Other devices external to memory device 100 (e.g., a memory controller or a processor) may control the values of the control signals on lines 104. Specific values of a combination of the signals on lines 104 may produce a command (e.g., read, write, or erase command) that causes memory device 100 to perform a corresponding memory operation (e.g., read, write, or erase operation).

Memory device 100 can include sense and buffer circuitry 120 that can include components such as sense amplifiers and page buffer circuits (e.g., data latches). Sense and buffer circuitry 120 can respond to signals BL_SEL0 through BL_SELn from column access circuitry 109. Sense and buffer circuitry 120 can be configured to determine (e.g., by sensing) the value of information read from memory cells 102 (e.g., during a read operation) of blocks BLK0 through BLKi and provide the value of the information to lines (e.g., global data lines) 175. Sense and buffer circuitry 120 can also be configured to use signals on lines 175 to determine the value of information to be stored (e.g., programmed) in memory cells 102 of blocks BLK0 through BLKi (e.g., during a write operation) based on the values (e.g., voltage values) of signals on lines 175 (e.g., during a write operation).

Memory device 100 can include input/output (I/O) circuitry 117 to exchange information between memory cells 102 of blocks BLK0 through BLKi and lines (e.g., I/O lines) 105. Signals DQ0 through DQN on lines 105 can represent information read from or stored in memory cells 102 of blocks BLK0 through BLKi. Lines 105 can include nodes within memory device 100 or pins (or solder balls) on a package where memory device 100 can reside. Other devices external to memory device 100 (e.g., a memory controller or a processor) can communicate with memory device 100 through lines 103, 104, and 105.

Memory device 100 can receive a supply voltage, including supply voltages Vcc and Vss. Supply voltage Vss can operate at a ground potential (e.g., having a value of approximately zero volts). Supply voltage Vcc can include an external voltage supplied to memory device 100 from an external power source such as a battery or alternating current to direct current (AC-DC) converter circuitry.

Each of memory cells 102 can be programmed to store information representing a value of at most one bit (e.g., a single bit), or a value of multiple bits such as two, three, four, or another number of bits. For example, each of memory cells 102 can be programmed to store information representing a binary value “0” or “1” of a single bit. The single bit per cell is sometimes called a single-level cell. In another example, each of memory cells 102 can be programmed to store information representing a value for multiple bits, such as one of four possible values “00”, “01”, “10”, and “11” of two bits, one of eight possible values “000”, “001”, “010”, “011”, “100”, “101”, “110”, and “111” of three bits, or one of other values of another number of multiple bits (e.g., more than three bits in each memory cell). A cell that has the ability to store multiple bits is sometimes called a multi-level cell (or multi-state cell).

Memory device 100 can include a non-volatile memory device, and memory cells 102 can include non-volatile memory cells, such that memory cells 102 can retain information stored thereon when power (e.g., voltage Vcc, Vss, or both) is disconnected from memory device 100. For example, memory device 100 can be a flash memory device, such as a NAND flash (e.g., 3D NAND) or a NOR flash memory device, or another kind of memory device, such as a variable resistance memory device (e.g., a phase change memory device or a resistive Random Access Memory (RAM) device).

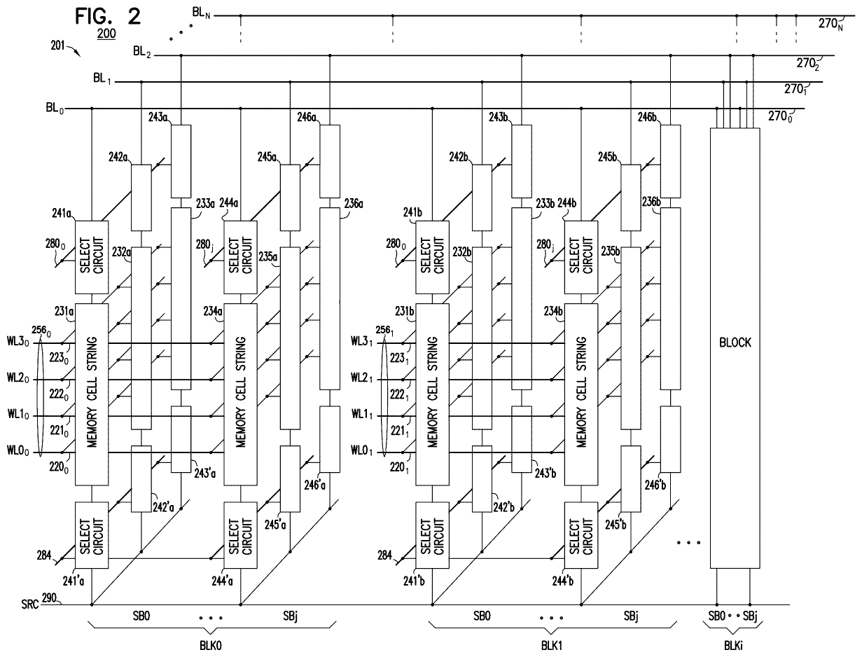

One of ordinary skill in the art may recognize that memory device 100 may include other components, several of which are not shown in FIG. 1 so as not to obscure the example embodiments described herein. At least a portion of memory device 100 can include structures and perform operations similar to or identical to the structures and operations of any of the memory devices described below with reference to FIG. 2 through FIG. 26B.

FIG. 2 shows a general schematic diagram of a portion of a memory device 200 including a memory array 201 having blocks (blocks of memory cells) BLK0 through BLKi and sub-blocks SB0 through SBj in each of the blocks, according to some embodiments described herein. Memory device 200 can correspond to memory device 100 of FIG. 1. For example, memory array 201 can form part of memory array 101 of FIG. 1.

As shown in FIG. 2, each sub-block (e.g., SB0 or SBj) has its own memory cell strings that can be associated with (e.g., coupled to) respective select circuits. The sub-blocks of the blocks (e.g., blocks BLK0 through BLKi) of memory device 200 can have the same number of memory cell strings and associated select circuits. For example, sub-block SB0 of block BLK0 has memory cell strings 231a, 232a, and 233a and associated select circuits (e.g., drain select circuits) 241a, 242a, and 243a, respectively, and select circuits (e.g., source select circuits) 241′a, 242′a, and 243′a, respectively. In another example, sub-block SBj of block BLK0 has memory cell strings 234a, 235a, and 236a and associated select circuits (e.g., drain select circuits) 244a, 245a, and 246a, respectively, and select circuits (e.g., source select circuits) 244′a, 245′a, and 246′a, respectively.

Similarly, sub-block SB0 of block BLK1 has memory cell strings 231b, 232b, and 233b, and associated select circuits (e.g., drain select circuits) 241b, 242 b, and 243 b, respectively, and select circuits (e.g., source select circuits) 241′b, 242′b, and 243′b, respectively. Sub-block SBj of block BLK1 has memory cell strings 234b, 235b, and 236b, and associated select circuits (e.g., drain select circuits) 244b, 245b, and 246b, respectively, and select circuits (e.g., source select circuits) 244′b, 245′b, and 246′b, respectively.

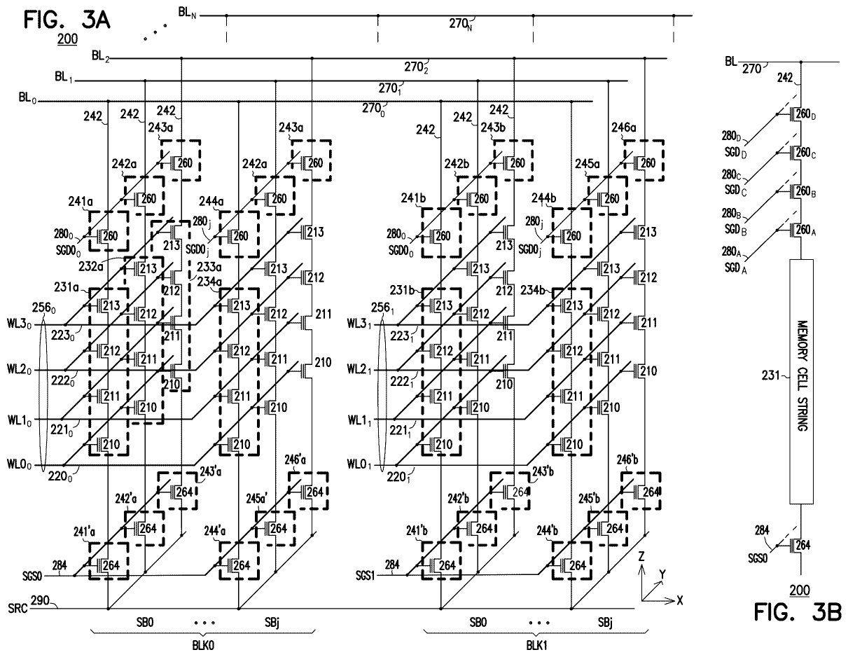

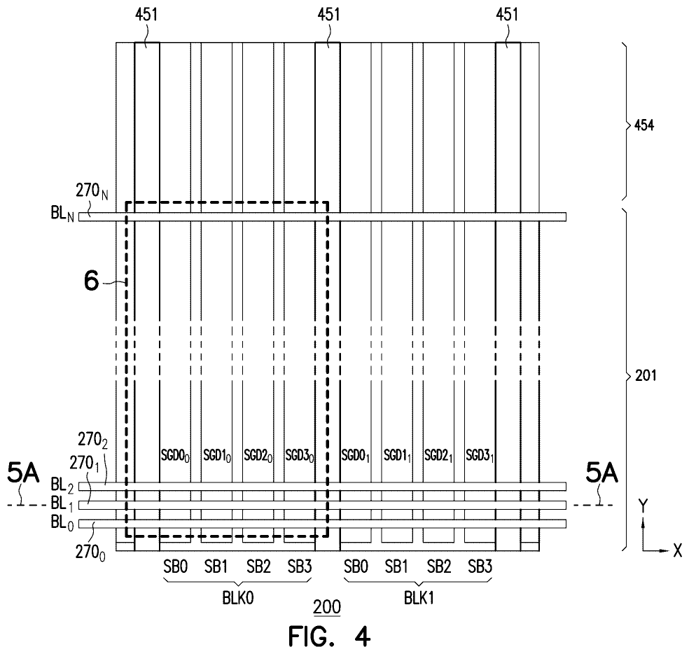

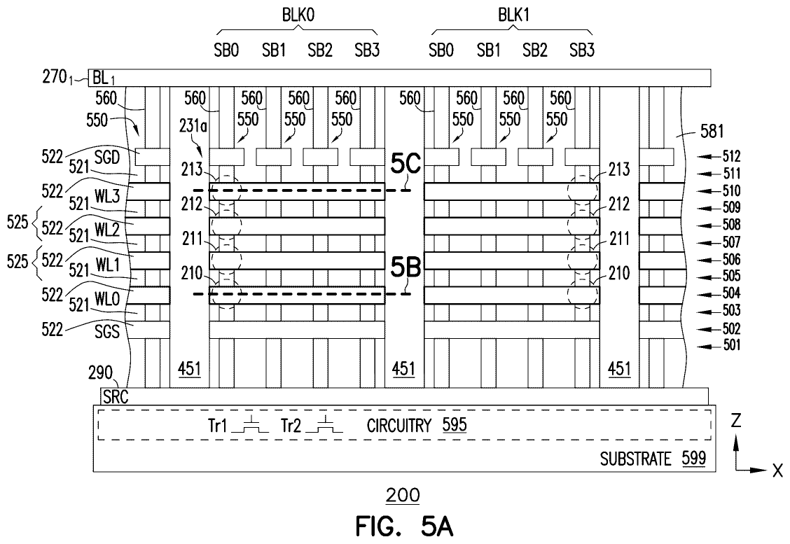

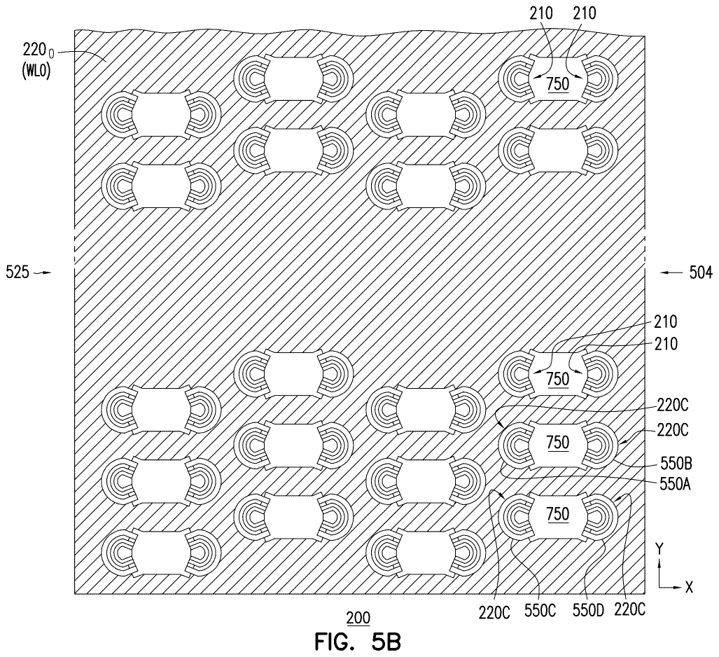

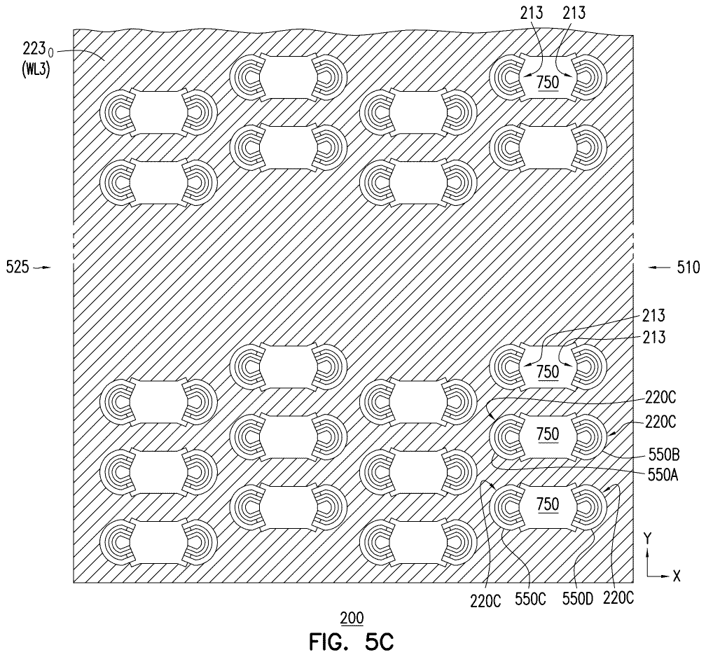

FIG. 2 shows an example of three memory cell strings and their associated circuits in a sub-block (e.g., in sub-block SB0). The number of memory cell strings and their associated select circuits in each sub-block of blocks BLK0 through BLKi can vary. Each of the memory cell strings of memory device 200 can include series-connected memory cells (shown in detail in FIG. 3A and FIG. 4) included in a memory cell pillar (e.g., pillar 550 in FIG. 5A) where the series-connected memory cells can be located (e.g., vertically located) along a respective portion of the pillar.

As shown in FIG. 2, memory device 200 can include data lines 270₀ through 270_{N} that carry signals BL₀ through BL_{N}, respectively. Each of data lines 270₀ through 270_{N} can be structured as a conductive line that can include conductive materials (e.g., conductively doped polycrystalline silicon (doped polysilicon), metals, or other conductive materials).

The memory cell strings of blocks BLK0 through BLKi can share data lines 270₀ through 270_{N} to carry information (in the form of signals) read from or to be stored in memory cells of selected memory cells (e.g., selected memory cells in block BLK0 or BLK1) of memory device 200. For example, memory cell strings 231a, 234a (of block BLK0), 231b and 234b (of block BLK1) can share data line 270₀. Memory cell strings 232a, 235a (of block BLK0), 232b and 235b (of block BLK1) can share data line 270₁. Memory cell strings 233a, 236a (of block BLK0), 233b and 236b (of block BLK1) can share data line 270₂.

Memory device 200 can include a source (e.g., a source line, a source plate, or a source region) 290 that can carry a signal (e.g., a source line signal) SRC. Source 290 can be structured as a conductive line or a conductive plate (e.g., conductive region) of memory device 200. Source 290 can be a common source (e.g., common source plate or common source region) of blocks BLK0 through BLKi. Alternatively, each of blocks BLK0 through BLKi can have its own source similar to source 290. Source 290 can be coupled to a ground connection of memory device 200.

Each of the blocks BLK0 through BLKi can have its own group of control gates for controlling access to memory cells of the memory cell strings of the sub-block of a respective block. As shown in FIG. 2, memory device 200 can include control gates (e.g., word lines) 220₀, 221₀, 222₀, and 223₀ in block BLK0 that can be part of conductive paths (e.g., access lines) 256₀ of memory device 200. Memory device 200 can include control gates (e.g., word lines) 220₁, 221₁, 222₁, and 223₁ in block BLK1 that can be part of other conductive paths (e.g., access lines) 256₁ of memory device 200. Conductive paths 256₀ and 256₁ can correspond to part of access lines 150 of memory device 100 of FIG. 1.

As shown in FIG. 2, control gates 220₀, 221₀, 222₀, and 223₀ can be electrically separated from each other. Control gates 220₁, 221₁, 222₁, and 223₁ can be electrically separated from each other. Control gates 220₀, 221₀, 222₀, and 223₀ can be electrically separated from control gates 220₁, 221₁, 222₁, and 223₁. Thus, blocks BLK0 through BLKi can be accessed separately (e.g., accessed one at a time).

FIG. 2 shows memory device 200 including four control gates in each of blocks BLK0 through BLKi as an example. The number of control gates of the blocks (e.g., blocks BLK0 through BLKi) of memory device 200 can be different from four. For example, each of blocks BLK0 through BLKi can include up to hundreds of control gates (or more than hundreds of control gates).

Each of control gates 220₀, 221₀, 222₀, and 223₀ can be part of a structure (e.g., a level) of a conductive material (e.g., a layer of conductive material) located in a level of memory device 200. Control gates 220₀, 221₀, 222₀, and 223₀ can carry corresponding signals (e.g., word line signals) WL0₀, WL1₀, WL2₀, and WL3₀. Memory device 200 can use signals WL0₀, WL1₀, WL2₀, and WL3₀ to selectively control access to memory cells of block BLK0 during an operation (e.g., read, write, or erase operation).

Each of control gates 220₁, 221₁, 222₁, and 223₁ can be part of a structure (e.g., a level) of a conductive material (e.g., a layer of conductive material) located in a level of memory device 200. Control gates 220₁, 221₁, 222₁, and 223₁ can carry corresponding signals (e.g., word line signals) WL0₁, WL1₁, WL2₁, and WL3₁. Memory device 200 can use signals WL0₁, WL1₁, WL2₁, and WL3₁ to selectively control access to memory cells of block BLK1 during an operation (e.g., read, write, or erase operation).

In this description, a material can include a single material (e.g., a single layer of material) or a combination of multiple materials (e.g., multiple layers of material). For example, a conductive material can include a single conductive material (e.g., a single layer of conductive material) or a combination of multiple conductive materials (e.g., multiple layers of different conductive materials). In another example, a dielectric material can include a single dielectric material (e.g., a single layer of dielectric material) or a combination of multiple dielectric materials (e.g., multiple layers of different dielectric materials). In this description, a dielectric structure can include a single dielectric material (e.g., a single layer of dielectric material) or a combination of multiple dielectric materials (e.g., multiple layers of different dielectric materials).

As shown in FIG. 2, in sub-block SB0 of block BLK0, memory device 200 can include a select line (e.g., drain select line) 280₀ that can be shared by select circuits 241a, 242a, and 243a. In sub-block SBj of block BLK0, memory device 200 can include a select line (e.g., drain select line) 280ⱼ that can be shared by select circuits 244a, 245a, and 246a. Block BLK0 can include a select line (e.g., source select line) 284 that can be shared by select circuits 241′a, 242′a, 243′a, 244′a, 245′a, and 246′a.

In sub-block SB0 of block BLK1, memory device 200 can include a select line (e.g., drain select line) 280₀, which is electrically separated from select line 280₀ of block BLK1. Select line 280₀ of block BLK1 can be shared by select circuits 241b, 242b, and 243b. In sub-block SBj of block BLK1, memory device 200 can include a select line (e.g., drain select line) 280ⱼ that can be shared by select circuits 244b, 245b, and 246b. Select lines 280₀ and 280ⱼ of block BLK1 are electrically separated from select lines 280₀ and 280ⱼ of block BLK0. Block BLK1 can include a select line (e.g., source select line) 284 that can be shared by select circuits 241′b, 242′b, 243′b, 244′b, 245′b, and 246′b.

FIG. 2 shows an example where memory device 200 includes one drain select line (e.g., select line 280₀) shared by select circuits (e.g., select circuits 241a, 242a, or 243a) in a sub-block (e.g., sub-block SB0 of block BLK0). However, memory device 200 can include multiple drain select lines shared by select circuits in a sub-block. FIG. 2 shows an example where memory device 200 includes one source select line (e.g., select line 284) shared by source select circuits (e.g., select circuits 241′a, 242′a, or 243′a) in a sub-block (e.g., sub-block SB0 of block BLK0). However, memory device 200 can include multiple source select lines shared by source select circuits in a sub-block.

In FIG. 2, each of the drain select circuits of memory device 200 can include a drain select gate (e.g., a transistor, shown in FIG. 3A) between a respective data line and a respective memory cell string. The drain select gate (e.g., transistor) can be controlled (e.g., turned on or turned off) by a signal on the respective drain select line based on voltages provided to the signal.

In FIG. 2, each of the source select circuits of memory device 200 can include a source select gate (e.g., a transistor, shown in FIG. 3A) coupled between source 290 and a respective memory cell string. The source select gate (e.g., transistor) can be controlled (e.g., turned on or turned off) by a signal on a respective source select line based on a voltage provided to the signal.

FIG. 3A shows a detailed schematic diagram including blocks BLK0 and BLK1 of memory device 200 of FIG. 2, according to some embodiments described herein. In FIG. 3A, directions X, Y, and Z in FIG. 3A can be relative to the physical directions (e.g., three dimensional (3D) dimensions) of the structure of memory device 200. For example, the Z-direction can be a direction perpendicular to (e.g., vertical direction with respect to) a substrate of memory device 200 (e.g., a substrate 599 shown in FIG. 5A). The Z-direction is perpendicular to the X-direction and Y-direction (e.g., the Z-direction is perpendicular to an X-Y plane of memory device 200).

For simplicity, only some of the memory cell strings and some of the select circuits of memory device 200 of FIG. 2 are labeled in FIG. 3A. As shown in FIG. 3A, each select line can carry an associated separate select signal. For example, in sub-block SB0 of block BLK0, select line (e.g., drain select line) 280₀ can carry signal (e.g., drain select-gate signal) SGD0₀. In sub-block SBj of block BLK0, select line (e.g., drain select line) 280ⱼ can carry signal (e.g., drain select-gate signal) SGD0ⱼ. Sub-blocks SB0 and SBj of block BLK0 can share select line 284 that can carry signal (e.g., source select-gate signal) SGS0.

In sub-block SB0 of block BLK1, select line (e.g., drain select line) 280₀ can carry signal (e.g., drain select-gate signal) SGD0₀. In sub-block SBj of block BLK1, select line (e.g., drain select line) 280ⱼ can carry signal (e.g., drain select-gate signal) SGD0ⱼ. Sub-blocks SB0 and SBj of block BLK1 can share select line 284 that can carry signal (e.g., source select-gate signal) SGS1.

For simplicity, similar or the same elements in the memory devices (e.g., memory device 200) described herein are given the same label. For example, as shown in FIG. 3A, similar drain select lines (and their associated signals) are given the same labels for simplicity. However, as shown in FIG. 3A, the drain select lines (from the same block or from different blocks) of memory device 200 are electrically separated from each other and carry different signals (although the signals are given the same labels).

As shown in FIG. 3A, memory device 200 can include memory cells 210, 211, 212, and 213; select gates (e.g., drain select gates or transistors) 260; and select gates (e.g., source select gates) 264 that can be physically arranged in three dimensions (3D), such as X, Y, and Z direction (e.g., dimensions), with respect to the structure (shown in FIG. 4) of memory device 200.

In FIG. 3A, each of the memory cell strings (e.g., memory cell string 231a) of memory device 200 can include series-connected memory cells that include one of memory cells 210, one of memory cells 211, one of memory cells 212, and one of memory cells 213. FIG. 3A shows an example of four memory cells 210, 211, 212, and 213 in each memory cell string. The number of memory cells in each memory cell string can vary. For example, each memory string can include up to hundreds (or more) of memory cells.

As shown in FIG. 3A, memory device 200 can include conductive connections 242 coupled between respective select gates 260 and respective data lines 270₀ through 270_{N}. In the physical structure of memory device 200, each conductive connection 242 is part of a contact structure (e.g., contact structure 560 in FIG. 5A) associated with a memory cell pillar (e.g., pillar 550 in FIG. 5A) of memory device 200.

As shown in FIG. 3A, each drain select circuit (e.g., select circuit 241a) can include one of select gates 260. Each source select circuit (e.g., select circuit 241′a) can include one of select gates 264.

Each select gate 260 in FIG. 3A can operate like a transistor. For example, select gate 260 of select circuit 241a can operate like a field effect transistor (FET), such as a metal-oxide semiconductor FET (MOSFET). An example of such a MOSFET includes an n-channel MOS (NMOS) transistor.

A select line (e.g., select line 280₀ of sub-block SB0 of block BLK0) can carry a signal (e.g., signal SGD0₀) but it does not operate like a switch (e.g., a transistor). A select gate (e.g., select gate 260 of select circuit 241a) can receive a signal (e.g., signal SGD0₀) from a respective select line (e.g., select line 280₀ of sub-block SB0 of block BLK0) and can operate like a switch (e.g., a transistor).

In the physical structure of memory device 200, a select line (e.g., select line 280₀ of sub-block SB0 of block BLK0) can be a structure (e.g., a level) of a conductive material (e.g., a layer (e.g., a piece) or a region of conductive material) located in a single level of memory device 200. The conductive material can include metal, doped polysilicon, or other conductive materials.

In the physical structure of memory device 200, a select gate (e.g., select gate 260 of select circuit 241a of sub-block SB0 of block BLK0) can include (can be formed from) a portion of the conductive material of a respective select line (e.g., select line 280₀ of sub-block SB0 of block BLK0), a portion of a channel material (e.g., polysilicon channel), and a portion of a dielectric material (e.g., similar to a gate oxide of a transistor (e.g., FET)) between the portion of the conductive material and the portion of the channel material.

FIG. 3A shows an example where memory device 200 includes one drain select gate (e.g., select gate 260) in each drain select circuit, and one source select gate (e.g., select gate 264) in each source select circuit coupled to a memory cell string. However, memory device 200 can include multiple drain select gates (e.g., multiple select gates 260 connected in series) in each drain select circuit, multiple source select gates (e.g., multiple select gates 264 connected in series) in each source select circuit, or both multiple drain select gates and multiple source select gates coupled to a memory cell string.

FIG. 3B shows an example of memory device 200 including four select gates (e.g., four drain select gates) 260_{A}, 260_{B}, 260_{C}, and 260_{D} associated with four select lines 280_{A}, 280_{B}, 280_{C}, and 280_{D.} Memory device 200 can use signals SGD_{A}, SGD_{B}, SGD_{C}, and SGD_{D} on select lines 280_{A}, 280_{B}, 280_{C}, and 280_{D}, respectively, to control (turn on or turn off) select gates 260_{A}, 260_{B}, 260_{C}, and 260_{D}, respectively. Data line 270 and associated signal BL can be one of data lines 270₀ through 270_{N} associated with one of signals BL₀ through BL_{N}, respectively. Memory cell string 231 and associated conductive connection 242 can be one of the memory cell strings (e.g., memory cell string 231a) associated with conductive connection 242 of memory device 200 of FIG. 3A.

FIG. 3B shows one source select gate (e.g., select gate 264) and one source select signal (e.g., signal SGS0) on a source select line (e.g., select line 284). However, memory device 200 can include two or more source select gates (in the Z-direction) like select gates 260_{A}, 260_{B}, 260_{C}, and 260_{D}.

FIG. 4 shows a top view of a structure of a portion of memory device 200 of FIG. 2 and FIG. 3A including a region of memory array 201 including blocks BLK0 and BLK1, a region 454, and structures 451 between blocks, according to some embodiments described herein. For simplicity, some elements of memory device 200 (and other memory devices described herein) may be omitted from a particular figure of the drawings so as not to obscure the view or the description of the element (or elements) being described in that particular figure. Also, for simplicity, cross-sectional lines (e.g., hatch lines) are omitted from some or all the elements shown in the drawings described herein. Some elements of memory device 200 may be omitted from a particular figure of the drawings so as not to obscure the view or the description of the element (or elements) being described in that particular figure. Further, the dimensions (e.g., physical structures) of the elements of memory device 200 (and other memory devices) in the drawings described herein are not scaled. Moreover, the description of the same elements of memory device 200 described above with reference to FIG. 2 and FIG. 3A are also not repeated.

In FIG. 4, structures 451 can be formed to separate (physically separate) one block and another block of memory device 200. Two adjacent blocks (e.g., blocks BLK0 and BLK1) can be separated from each other by one of structures 451. Each structure 451 can have a length in the Y-direction. Each structure 451 can include a dielectric material (e.g., silicon dioxide) or a combination of a dielectric material and additional material (e.g., a non-conductive material). Each structure 451 can include a slit (not labeled) and materials (not labeled) formed in (e.g., filled in) the slit. The slit can include (or can be part of) a trench between adjacent blocks (e.g., blocks BLK0 and BLK1). Structures 451 can be called a dielectric structure or a slit structures. The regions of memory device 200 at which structures 451 are located can be called slit regions.

Region 454 can include conductive contacts (not shown) coupled to respective control gates (e.g., control gates 220₀, 221₀, 222₀, and 223₀ and control gates 220₁, 221₁, 222₁, and 223₁ in FIG. 3A) of memory device 200. The conductive contacts allow signals (e.g., signals WL0₀, WL1₀, WL2₀, and WL3₀, and signals WL0₁, WL1₁, WL2₁, and WL3₁ in FIG. 3A) to be provided to the control gates.

As shown in FIG. 4, block BLK0 can include sub-blocks (e.g., four sub-blocks) SB0, SB1, SB2, and SB3 and select lines (e.g., four drain select lines) associated with signals SGD0₀, SGD1₀, SGD2₀, and SGD3₀, respectively. The select lines can include respective conductive regions (e.g., conductive materials) that are electrically separated from each other (in the X-direction) and can be located on the same level (with respect to the Z-direction). The select lines associated with signals SGD0₀, SGD1₀, SGD2₀, and SGD3₀ can be located over (with respect to the Z-direction) the control gates (under the select lines) of block BLK0. As shown in FIG. 4, each of the select lines (associated with signals SGD0₀, SGD1₀, SGD2₀, and SGD3₀) can have length in the Y-direction from memory array 201 to region 454. FIG. 4 shows an example where each block of memory device 200 can have four sub-blocks SB0, SB1, SB2, and SB3. However, the number of sub-blocks can be different from four.

Block BLK1 can have a structure like block BLK0. As shown in FIG. 4, block BLK1 can include sub-blocks SB0, SB1, SB2, and SB3 and select lines (e.g., drain select lines) SGD0₁, SGD1₁, SGD2₁, and SGD3₁.

As shown in FIG. 4, data lines 270₀ through 270_{N} can extend across (in the X-direction) the blocks (e.g., blocks BL0 and BL1) and can be shared by the blocks.

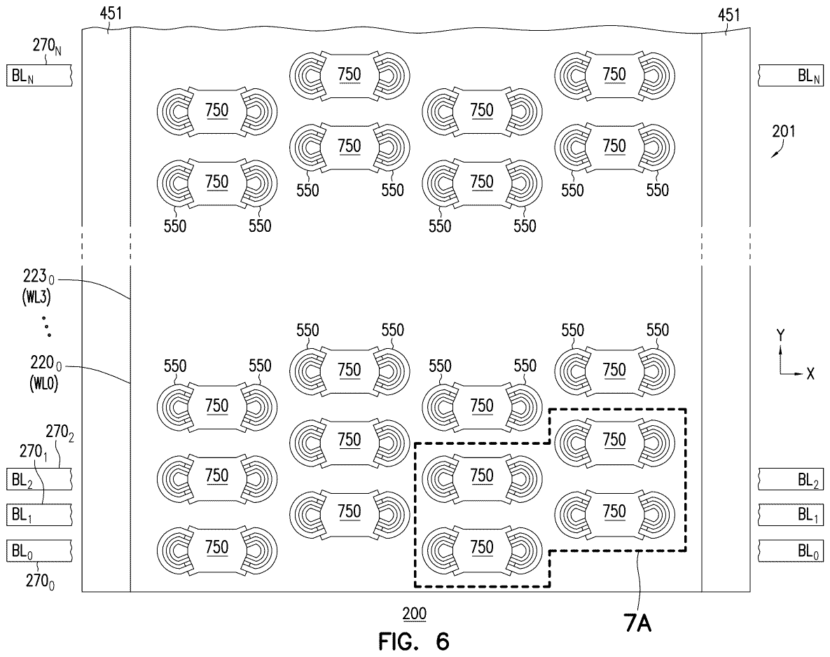

A side view (e.g., cross-section) at memory array (memory cell array) 201 of memory device 200 along line 5A-5A in FIG. 4 is shown in FIG. 5A. FIG. 6 show details of a portion (labeled “6”) of memory device 200 of FIG. 4.

FIG. 5A shows a side view (e.g., cross-section) of a structure of a portion of memory device 200 of FIG. 4 including tiers (tiers of materials) 525 that include respective memory cells and control gates associated with (e.g., to control) the memory cells, according to some embodiments described herein. FIG. 5A also partially shows other blocks (on the left and right sides of blocks BLK0 and BLK1) of memory device 200. FIG. 5B and FIG. 5C (described below) show top views along lines 5B-5B and 5C-5C at the control gates associated with signals WL0 and WL3.

As shown in FIG. 5A, memory device 200 can include a substrate 599, source 290 formed over substrate 599, and different levels 501 through 512 over substrate 599 in the Z-direction. Levels 501 through 512 are physical device levels of memory device 200 over substrate 599. Memory device 200 can include a dielectric material 581 formed over at least a portion of memory device 200. Memory cells 210, 211, 212, and 213 of the memory cell strings (e.g., memory cell string 231a in FIG. 3A) of respective sub-blocks SB0, SB1, SB2, and SB3 of each of blocks BLK0 and BLK1 can be formed over substrate 599 and source 290 (e.g., formed vertically in Z-direction in respective levels among levels 501 through 512).

As shown in FIG. 5A, data line 270₁ (associated with signal BL₁) can extend in the X-direction across the blocks (e.g., blocks BLK0 and BLK1 and other blocks) of memory device 200. Data line 270₁ can be shared by respective memory cell strings (including memory cell string 231a) of the blocks.

In FIG. 5A, the select lines (e.g., four drain select lines in the X-direction) indicated by signal SGD can correspond to respective select lines (e.g., drain select lines) of a respective block of blocks BLK0 and BLK1. For example, in sub-blocks SB0, SB1, SB2, and SB3 of block BLK0, the select lines (e.g., four drain select lines) indicated by signal SGD can correspond to respective select lines associated with signals SGD0₀, SGD1₀, SGD2₀, and SGD3₀ of block BLK0 shown in FIG. 4. In another example, in sub-blocks SB0, SB1, SB2, and SB3 of block BLK1, the select lines (e.g., four drain select lines in the X-direction) indicated by signal SGD can correspond to respective select lines associated with signals SGD0₁, SGD1₁, SGD2₁, and SGD3₁ of block BLK1 shown in FIG. 4.

As shown in FIG. 5A, the select lines (e.g., four drain select lines) in the same block (e.g., block BLK0) can include respective conductive regions (e.g., four conductive regions) that are electrically separated from each other and can be located on the same level (e.g., level 512) in the Z-direction of memory device 200 and located over the control gates (in the Z-direction) of the respective block.

The select lines (e.g., source select lines) indicated by signal SGS (on level 501) can correspond to respective select lines of blocks BLK0 and BLK1. For example, in block BLK0, the select line indicated by signal SGS can correspond to the select line (e.g., source select line) associated with signals SGS0 of block BLK0 shown in FIG. 3A. In another example, in block BLK1, the select line indicated by signal SGS can correspond to the select line (e.g., source select line) associated with signals SGS1 of block BLK1 shown in FIG. 3A.

In FIG. 5A, for simplicity, control gates (e.g., four control gates) of blocks BLK0 and BLK1 are indicated by the same signals WL0, WL1, WL2, and WL3. For example, in block BLK0, the control gates indicated by signals WL0, WL1, WL2, and WL3 can correspond to respective control gates 220₀, 221₀, 222₀, and 223₀ associated with signals WL0₀, WL1₀, WL2₀, and WL3₀, respectively, of block BLK0 shown in FIG. 3A. In another example, in block BLK1 in FIG. 5A, the control gates indicated by signals WL0, WL1, WL2, and WL3 can correspond to respective control gates 220₁, 221₁, 222₁, and 223₁ associated with signals WL0₁, WL1₁, WL2₁, and WL3₁, respectively, of block BLK1 shown in FIG. 3A.

As shown in FIG. 5A, memory device 200 can include dielectric materials (e.g., silicon dioxide) 521 located on levels 503, 505, 507, 509, and 511. Dielectric materials 521 in a respective block are interleaved with conductive materials 522. Conductive materials 522 can form respective control gates (associated with signals WL0, WL1, WL2, and WL3) in the respective block. As shown in FIG. 5A, dielectric materials 521 can be located on respective levels among levels 501 through 512. Conductive materials 522 can be located on respective levels (e.g., levels 502, 504, 506, 508, 510, and 512) among levels 501 through 512 that are interleaved with the levels of dielectric materials 521. Examples of conductive materials 522 (which form the control gates) include a single conductive material (e.g., single metal, e.g., tungsten) or a combination of different layers of conductive materials. For example, each of the control gates of blocks BLK0 and BLK1 can include (e.g., have multi-layers of) aluminum oxide, titanium nitride, tungsten.

As shown in FIG. 5A, dielectric materials 521 can form levels of dielectric materials 521. Conductive materials 522 can form levels of conductive materials 522 that are interleaved with the levels of dielectric materials 521. The levels of dielectric materials 521 and the levels of conductive materials 522 can form tiers 525 of memory device 200. Each tier 525 can include a level of dielectric material 521 and a level of conductive material 522. For simplicity, only some of tiers 525 are labeled in FIG. 5A. As shown in FIG. 5A, tiers 525 can be located one over another and can include respective levels of memory cells 210, 211, 212, and 213, and control gates associated with the memory cells. FIG. 5A shows a few tiers (e.g., only two tiers 525 are labeled) of memory device 200 as an example. However, memory device 200 can include up to hundreds of tiers (or more than hundreds of tiers).

As shown in FIG. 5A, memory device 200 can include pillars (memory cell pillars) 550 in blocks BLK0 and BLK1. Each of pillars 550 can be part of a respective memory cell string (e.g., memory cell string 231a). Each of the pillars 550 can have length extending through at least a portion of the levels of dielectric materials 521 and the levels of conductive materials 522 in the Z-direction (e.g., extending vertically from substrate 599) between substrate 599 and data line 270₁. As shown in FIG. 5A, the Z-direction is also a direction at which the length of pillar 550 extends from one tier to another tier, which is also a direction from levels of dielectric materials 521 to levels of conductive materials 522.

As shown in FIG. 5A, memory device 200 can include contact structures (e.g., data line contact structures) 560. Each pillar 550 can be coupled to a data line by a respective contact structure 560. Each contact structure 560 can be considered as part of a respective pillar 550 and can include a conductive material (or conductive materials) to allow electrical signal between pillar 550 and a respective data line.

As shown in FIG. 5A, memory cells 210, 211, 212, and 213 of respective memory cell strings (e.g., memory cell string 231a) can be located in different levels (e.g., levels 504, 506, 508, and 510) in the Z-direction of memory device 200. The control gates (associated with signals WL0, WL1, WL2, and WL3) of each of blocks BLK0 and BLK1 can be located on the same levels (e.g., levels 504, 506, 508, and 510) at which memory cells 210, 211, 212, and 213 are located. Thus, memory cells 210, 211, 212, and 213 and the control gates of blocks BLK0 and BLK1 can be located (e.g., vertically located) along respective portions (e.g., portions on levels 504, 506, 508, and 510) of pillars 550 in the Z-direction.

Substrate 599 of memory device 200 can include monocrystalline (also referred to as single-crystal) semiconductor material. For example, substrate 599 can include monocrystalline silicon (also referred to as single-crystal silicon). The monocrystalline semiconductor material of substrate 599 can include impurities, such that substrate 599 can have a specific conductivity type (e.g., n-type or p-type).

As shown in FIG. 5A, memory device 200 can include circuitry 595 located in (e.g., formed in) substrate 599. At least a portion of the circuitry 595 can be located in a portion of substrate 599 that is under (e.g., directly under) memory cell strings of blocks BLK0 and BLK1. Circuitry 595 can include transistors (e.g., Tr1 and Tr2) that can be part of decoder circuits, driver circuits (e.g., word line drivers), buffers, sense amplifiers, charge pumps, and other circuitry of memory device 200.

In FIG. 5A, source 290 can include a conductive material (or materials, e.g., different levels of different materials) and can have a length extending in the X-direction. FIG. 5A shows an example where source 290 can be formed over a portion of substrate 599 (e.g., by depositing a conductive material over substrate 599). Alternatively, source 290 can be formed in or formed on a portion of substrate 599 (e.g., by doping a portion of substrate 599).

The select lines (associated with signals SGS and SGD) of blocks BLK0 and BLK1 can have the same material (or materials) as the control gates (associated with signals WL0, WL1, WL2, and WL3) of blocks BLK0 and BLK1. Alternatively, the select gates associated with signal SGS, SGD, or both have material (or materials) different from the material of the control gates.

In FIG. 5B, pillars (memory cell pillars) 550A, 550B, 550C, and 550D are four of pillars 550 of FIG. 5A. For simplicity, in FIG. 5B, only some of the pillars of memory device 200 are labeled. In this description, pillar and memory cell pillars are used interchangeably.

FIG. 5B shows top views along lines 5B-5B at the control gate associated with signals WL0 that corresponds to control gate 220₀ of FIG. 3A. As shown in FIG. 5B, control gate 220₀ can include concave portions 220C adjacent (e.g., contacting) respective portions of pillars 550A, 550B, 550C, and 550D.

As shown in FIG. 5B, the pillars of memory device 200 can be arranged in rows next to each other in the X-direction. Each row can include pairs of memory cell pillars. Each pair of memory cell pillars includes two adjacent pillars in the X-direction. For example, FIG. 5B shows a pair of pillars 550A and 550B, and another pair of pillars 550C and 550D. FIG. 5B shows four rows (located next to each other in the X-direction) of pairs of memory cell pillars as an example. However, memory device 200 can include numerous (greater than four) rows of pairs of memory cell pillars.

As shown in FIG. 5B, memory cells 210 of tier 525 on level 504 can be arranged in rows (side-by-side) in the X-direction. In a tier (e.g., tier 525), each row can include pairs of memory cells. Each pair of memory cells includes two adjacent memory cells in the X-direction. For example, FIG. 5B shows a pair of memory cells 210 associated with pillars 550A and 550B, and another pair of memory cells 210 associated with pillars 550C and 550D. As shown in FIG. 5B, pillars 550A, 550B, 550C, and 550D can be formed (e.g., arranged) such that pillar 550A can be closer to pillar 550C than pillar 550D, and pillar 550B can be closer to pillar 550D than pillar 550C. FIG. 5B shows four rows (in the X-direction) of pairs of memory cells 210 in tier 525 as an example. However, memory device 200 can include numerous (greater than four) rows of pairs of memory cells in each tier (e.g., in tier 525).

As shown in FIG. 5B, memory device 200 can include a dielectric structure 750 between two adjacent pillars (between two adjacent memory cells 210) and to separate (split) the adjacent pillars in the X-direction. For example, memory device 200 includes dielectric structure 750 between pillars 550A and 550B (between two adjacent memory cells 210 associated with pillars 550A and 550B). In another example, memory device 200 includes dielectric structure 750 between pillars 550C and 550D (between two adjacent memory cells 210 associated with pillars 550C and 550D). Each dielectric structure 750 can extend in the Z-direction from one tier 525 to another tier 525.

As shown in FIG. 5B, dielectric structures 750 between a pair of pillars (e.g., between pillars 550A and 550B) is separated from (is not contacting) dielectric structures 750 between another pair of pillars (e.g., between pillars 550C and 550D). Thus, as shown in FIG. 5B, dielectric structure 750 may not extend continuous (in the Y-direction) from a pair of pillars (e.g., pillar 550A and 550B) to another pair of pillars (e.g., pillar 550C and 550D).

FIG. 5C shows top views along lines 5C-5C at the control gate associated with signals WL3 that corresponds to control gate 223₀ of FIG. 3A. As shown in FIG. 5C, control gate 223₀ can include concave portions 220C adjacent (e.g., contacting) respective portions of pillars 550A, 550B, 550C, and 550D.

FIG. 5C shows a similar structure of memory device 200 like FIG. 5B. However, FIG. 5C shows different memory cells (e.g., memory cells 213) associated with control gate 223₀ of tier 525 on a different level 510 (instead of level 504) of memory device 200. Pillars 550A, 550B, 550C, and 550D and dielectric structure 750 in FIG. 5B are the same as pillars 550A, 550B, 550C, and 550D and dielectric structure 750 in FIG. 5B. As shown in FIG. 5C, dielectric structure 750 can also be between two adjacent memory cells 213 in tier 525. For example, one dielectric structure 750 can be between adjacent memory cells 213 associated with pillars 550A and 550B. In another example, another dielectric structure 750 can be between adjacent memory cells 213 associated with pillars 550C and 550D.

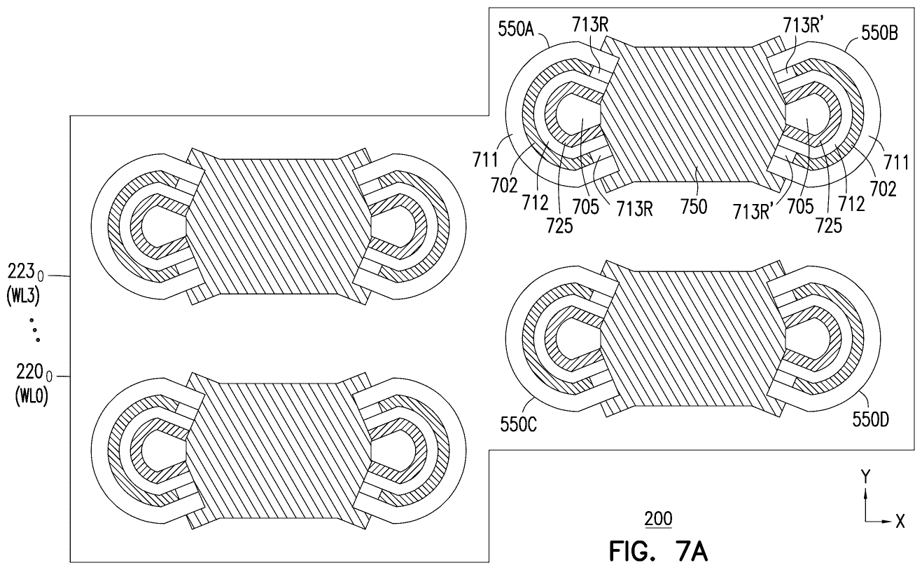

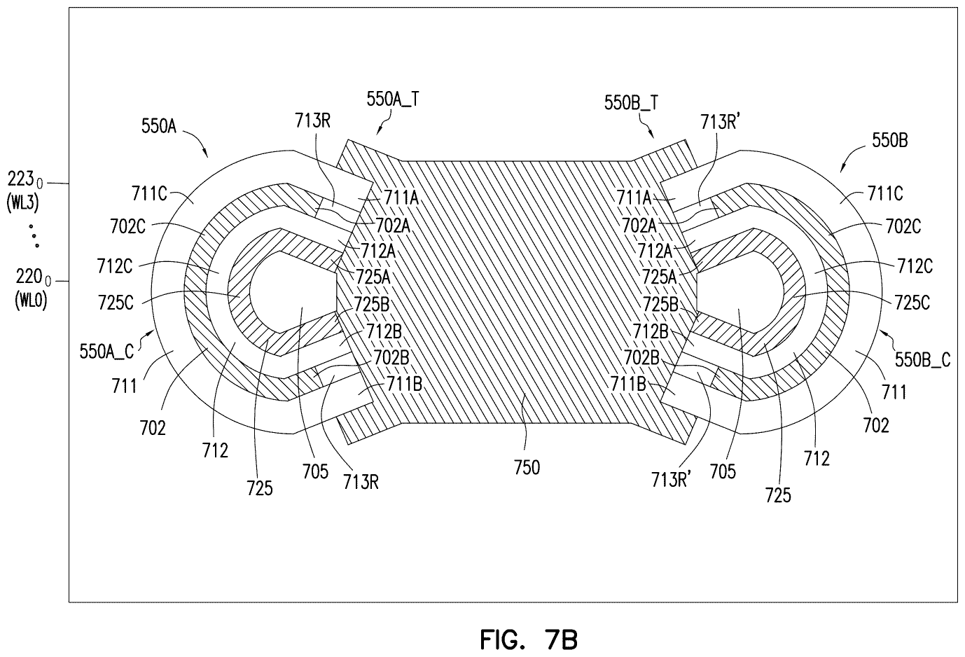

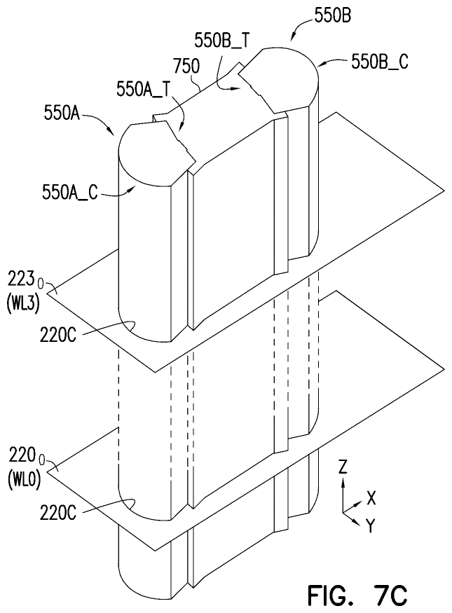

FIG. 6 shows top views of a structure of a portion of memory device 200 of FIG. 4, according to some embodiments described herein. As shown in FIG. 6, pillars 550 (shown in top view) can be located in the region included in memory array 201. Pillars 550 can extend in the Z-direction through control gates 220₀ through 223₀ that are located one over another (stacked in tiers 525 shown in FIG. 5A). In FIG. 6, data lines 270₀ through 270_{N} are partially shown for simplicity. Data lines 270₀ through 270_{N} can be located over and in electrical contact with pillars 550. Each pillar 550 can be coupled to a separate (e.g., unique) data line among data lines 270₀ through 270_{N}. For simplicity, connections (e.g., vertical connections in the Z-direction) between pillars 550 and data lines 270₀ through 270_{N} are not shown in FIG. 6. FIG. 7A show details of a portion (labeled “7A”) of memory device 200 of FIG. 6.

In FIG. 7A, pillars 550A, 550B, 550C, and 550D are four of pillars 550 of FIG. 6. For simplicity, in FIG. 7A, only some of the pillars of memory device 200 are labeled. For simplicity, the description here describes details of pillar 550A. Other pillars (e.g., pillars 550B, 550C, and 550D) include elements that are similar to (or the same as) those of pillar 550A.

As shown in FIG. 7A, pillar 550A can include a dielectric material 711, a dielectric material 712, a memory storage material 702 between dielectric materials 711 and 712, a semiconductor material 725 adjacent dielectric material 712, and a dielectric material 705 adjacent (e.g., at least partially surrounded by) semiconductor material 725. As shown in FIG. 7A, pillar 550A can include a recess (e.g., a cavity) 713R between (e.g., formed by) a portion of dielectric material 711, a portion of dielectric material 712, and a portion of memory storage material 702. Pillar 550A can also include a recess 713R′ between (e.g., formed by) a portion of dielectric material 711, a portion of dielectric material 712, and a portion of memory storage material 702. Each of recess 713R and 713R′ can be filled with a dielectric material (e.g., silicon dioxide).

Dielectric material 711 can include a charge blocking material (e.g., silicon dioxide). Dielectric material 712 can include charge tunneling material (e.g., silicon dioxide). Memory storage material 702 can include a material that can store a charge to represent the information stored in a memory cell (e.g., memory cell 210 or 213 in FIG. 5B or FIG. 5C). An example for memory storage material 702 include silicon nitride or other materials. Semiconductor material 725 is part of a conductive channel structure of pillar 550A that can form a circuit path (e.g., a current path) between a respective data line (e.g., data line 270₁ in FIG. 5A) and source 290 (FIG. 5A). Example materials for semiconductor material 725 include polysilicon or other materials. FIG. 7A shows an example structure (e.g., an ONOS (SiO₂, Si₃N₄, SiO₂, Si structure) of pillar 550A. However, pillar 550A can include other structures. For example, pillar 550A can include a SONOS (Si, SiO₂, Si₃N₄, SiO₂, Si) structure, a TANOS (TaN, Al₂O₃, Si₃N₄, SiO₂, Si) structure, a MANOS (metal, Al₂O₃, Si₃N₄, SiO₂, Si) structure, or other memory cell pillar structures.

Dielectric structure 750 can include a dielectric material (e.g., silicon dioxide) or a combination of different dielectric materials (e.g., different layers of dielectric materials). Dielectric material 705 can include silicon dioxide or other dielectric materials. In an alternative structure of memory device 200, dielectric structure 750 can be omitted from (e.g., not formed in) memory device 200, such that memory device 200 can have an empty region at the location of dielectric structure 750. Omitting dielectric structure 750 can lower potential electrostatic interference between two adjacent memory cells (e.g., between memory cells 210 in FIG. 5B or between memory cells 213 in FIG. 5C).

As shown in FIG. 7A, a cross-section of pillar 550A may not have a round shape (e.g., a ring shape, a circular, or an oval shape). As shown in FIG. 7A, the cross-section of pillar 550A (e.g., cross-section parallel to the X-Y plane) has a partial-round shape (e.g., partial-ring shape, partial-circular, or partial-oval shape). For example, as shown in FIG. 7A, each of dielectric material 711, dielectric material 712, memory storage material 702, and semiconductor material 725 can include two end portions and a curved (e.g., arc) middle portion, as shown in FIG. 7B.

FIG. 7B shows pillar 550A of FIG. 7A with labels associated with different portions of the materials of pillar 550A. As shown in FIG. 7B, dielectric material 711 can include an end portion (e.g., a distal end portion on one side of dielectric material 711) 711A, an end portion (e.g., a distal end portion on another side of dielectric material 711) 711B, and a portion (e.g., a middle portion between the distal end portions) 711C. As shown in FIG. 7B, portion 711C can have a curved shape that is adjacent (e.g., contacting) the concave portion of a respective control gate (e.g., concave portion 220C of control gate 220₀ of FIG. 5B) of memory device 200.

As shown in FIG. 7B, memory storage material 702 can include an end portion (e.g., a distal end portion on one side of memory storage material 702) 702A, an end portion (e.g., a distal end portion on another side of memory storage material 702) 702B, and a portion (e.g., a middle portion between the distal end portions) 702C. As shown in FIG. 7B, portion 702C can have a curved shape that is adjacent (e.g., contacting) portion 711C of dielectric material 711.

As shown in FIG. 7B, dielectric material 712 can include an end portion (e.g., a distal end portion on one side of dielectric material 712) 712A, an end portion (e.g., a distal end portion on another side of dielectric material 712) 712B, and a portion (e.g., a middle portion between the distal end portions) 712C. As shown in FIG. 7B, portion 712C can have a curved shape that is adjacent (e.g., contacting) portion 702C of memory storage material 702.

As shown in FIG. 7B, semiconductor material 725 can include an end portion (e.g., a distal end portion on one side of semiconductor material 725) 725A, an end portion (e.g., a distal end portion on another side of semiconductor material 725) 725B, and a portion (e.g., a middle portion between the distal end portions) 725C. As shown in FIG. 7B, portion 725C can have a curved shape that is adjacent (e.g., contacting) portion 712C of dielectric material 712. The shape of semiconductor material 725 having end portions 725A and 725B that are separated from each other at dielectric structure 750 can reduce or eliminate leakage of current associated with the conductive channel structure (which includes semiconductor material 725) of the pillar (e.g., pillar 550A) of memory device 200.

As shown in FIG. 7B, pillar 550A can include a curved portion 550A_C and a tapered portion 550A_T. Curved portion 550A_C can include portions (e.g., curved portions) 711C, 702C, 712C, and 725C of pillar 550A and at least part of material 705 of pillar 550A. Tapered portion 550A_T can include end portions 711A, 702A, 712A, 725A, 711B, 702B, 712B, and 725B of pillar 550A at least part of material 705 of pillar 550A.

In FIG. 7B, like pillar 550A, pillar 550B also include a curved portion 550BA_C and a tapered portion 550B_T. Curved portion 550B_C can include portions (e.g., curved portions) 711C, 702C, 712C, and 725C of pillar 550B and at least part of material 705 of pillar 550B. Tapered portion 550B_T can include end portions 711A, 702A, 712A, 725A, 711B, 702B, 712B, and 725B of pillar 550B at least part of material 705 of pillar 550B.

FIG. 7C show a perspective view of pillars 550A and 550B. For simplicity, FIG. 7C shows an outline structure of a portion of memory device 200 and omits detailed structures of pillars 550A and 550B, dielectric structure 750, and control gates 220₀ and 223₀. As shown in FIG. 7C, dielectric structure 750 is adjacent and between tapered portion 550A_T of pillar 550A and tapered portion 550B_T of pillar 550B.

Each of pillars 550A and 550B may not have a complete cylindrical shape. As shown in FIG. 7C, each of pillars 550A and 550B has partial-cylindrical shape (e.g., semi-cylindrical shape) formed by a curved portion (e.g., curved portion 550A_C or 550B_C) and a tapered portion (e.g., tapered portion 550A_T or 550B_T). As shown in FIG. 7C, pillars 550A and 550B can extend in the Z-direction through control gates 220₀ and 223₀. Portion 550A_C and 550B_C can be adjacent respective concave portions 220C of control gates 220₀ and 223₀.

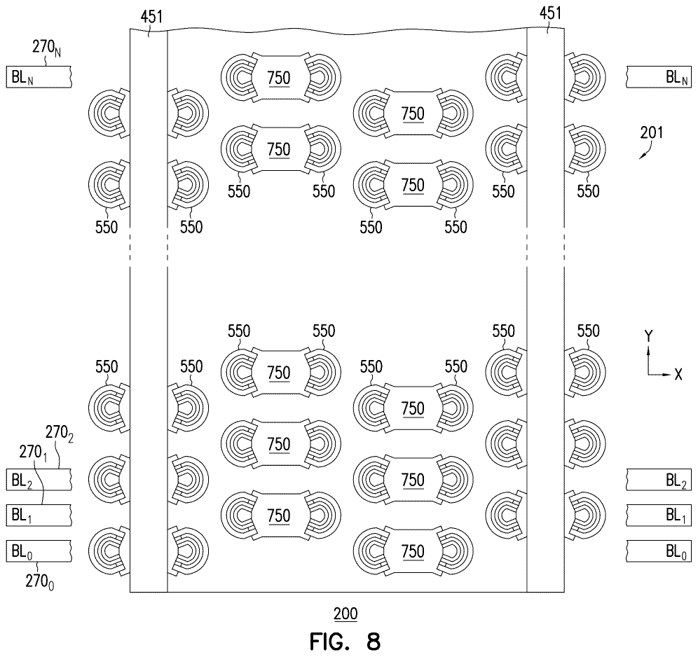

FIG. 8 shows a variation of memory device 200, according to some embodiments described herein. As shown in FIG. 8, dielectric structure 451 can be formed continuously through locations (e.g., like the location of dielectric structure 750) between pairs of pillars 550 that are located in the same row.

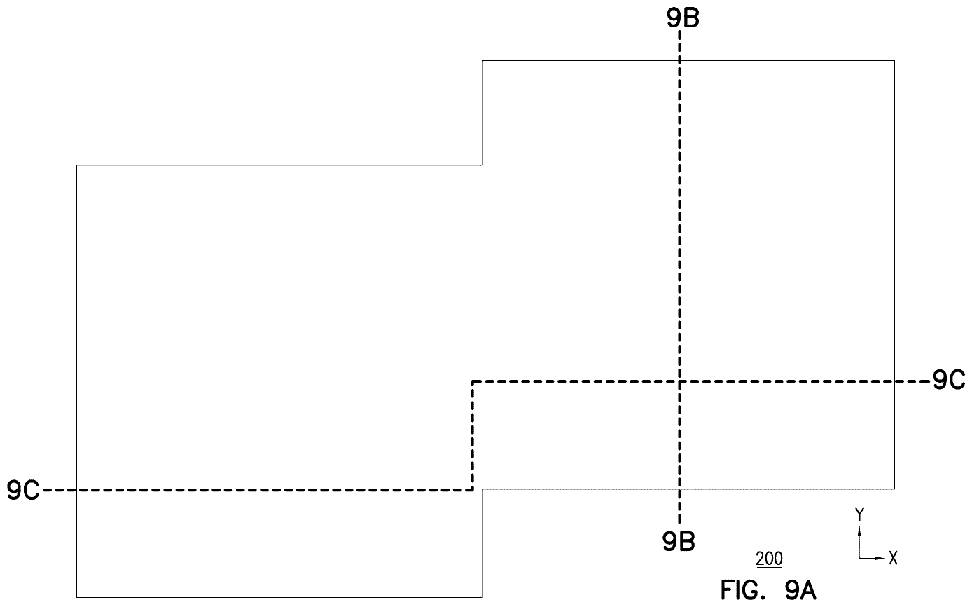

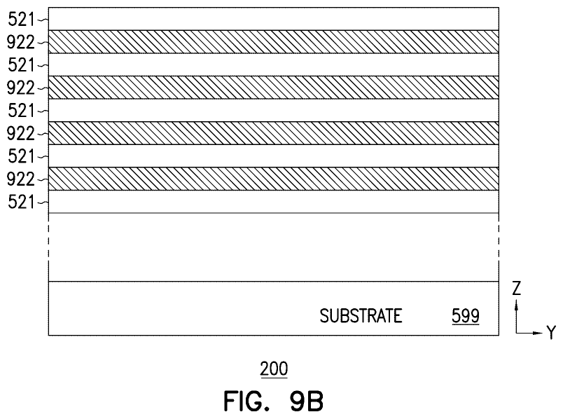

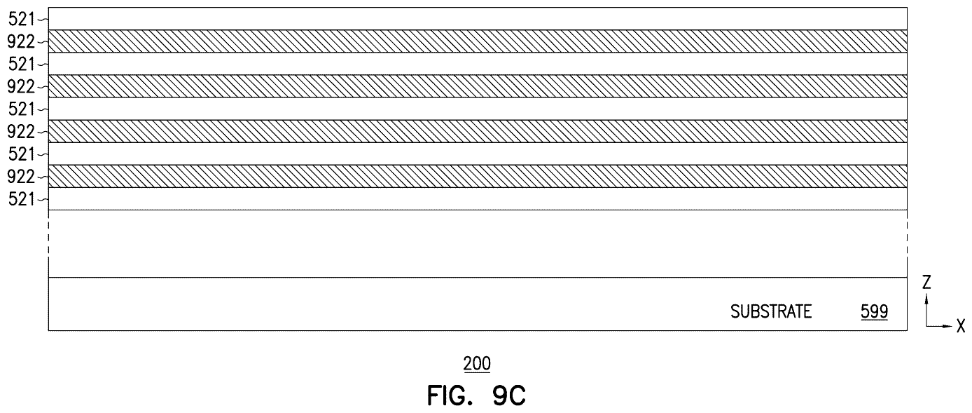

FIG. 9A through FIG. 26B show different views of structures during processes of forming memory device 200 of FIG. 2 through FIG. 7C, according to some embodiments described herein. In FIG. 2 through FIG. 26B, the same materials and elements are given the same labels.

FIG. 9A shows a top view of memory device 200. FIG. 9B shows a side view (e.g., a cross-section) in the Y-Z direction of memory device 200 taken along line 9B-9B of FIG. 9A. FIG. 9C shows a side view (e.g., a cross-section) in the X-Z direction of memory device 200 taken along line 9C-9C of FIG. 9A.

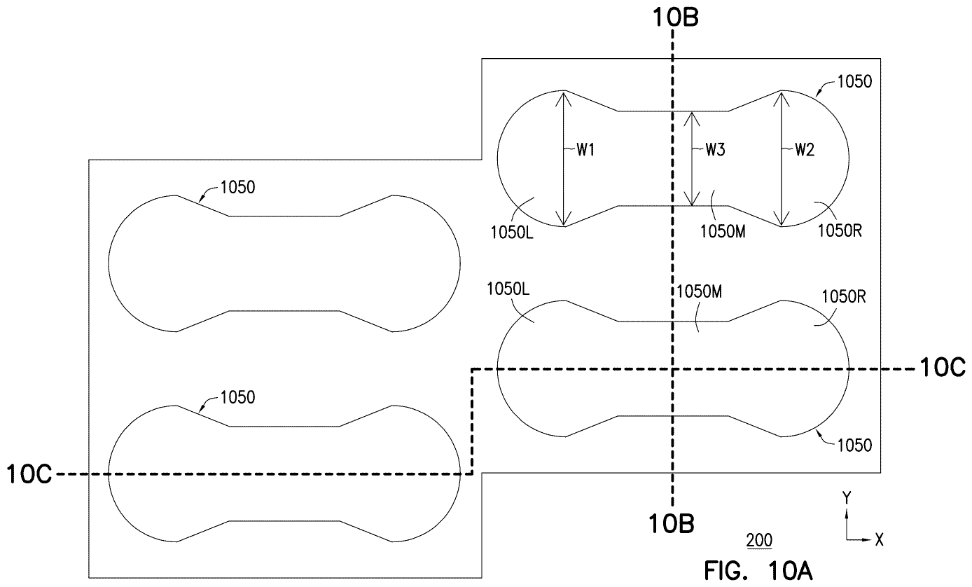

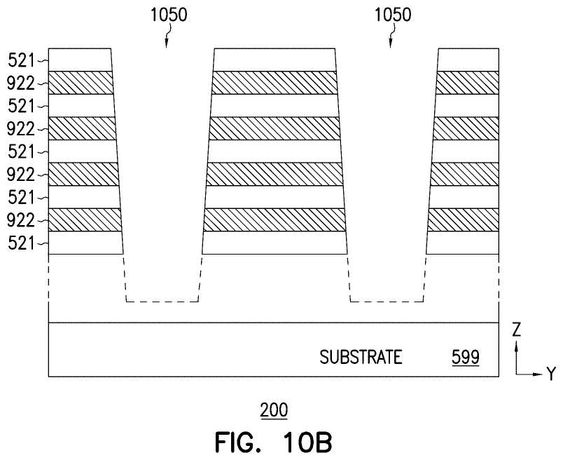

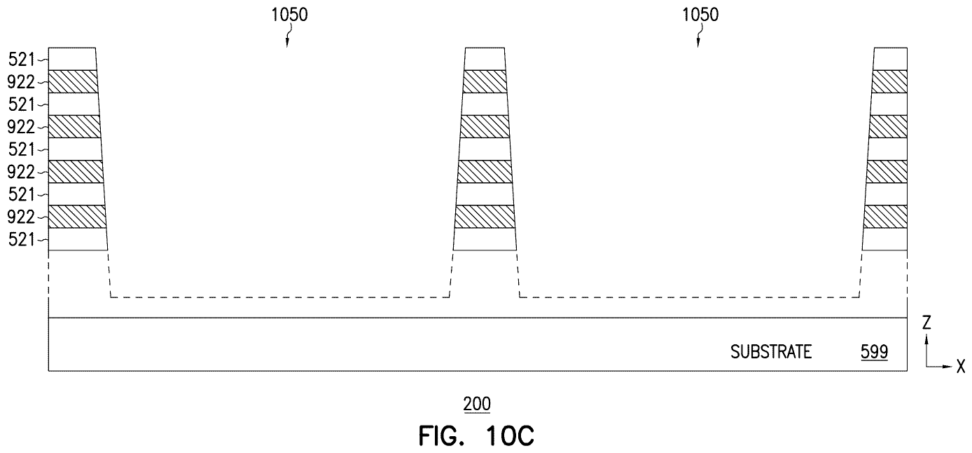

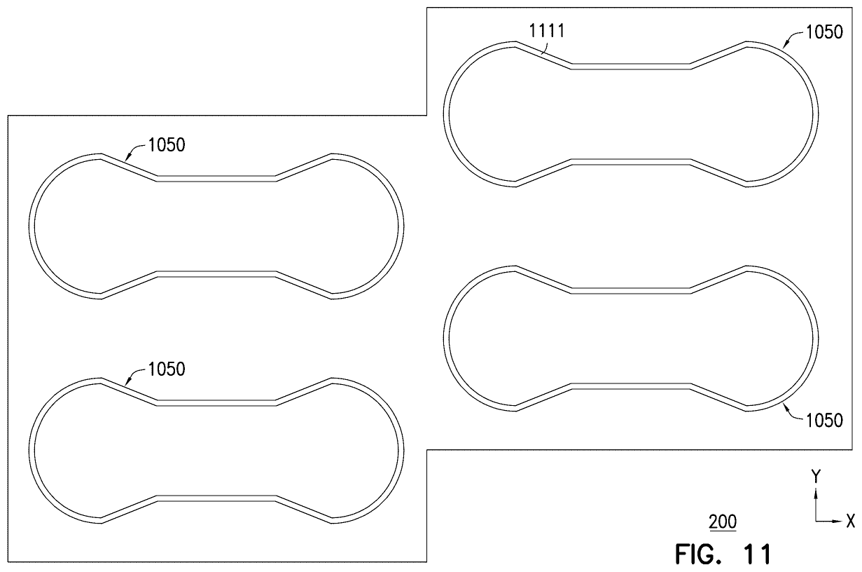

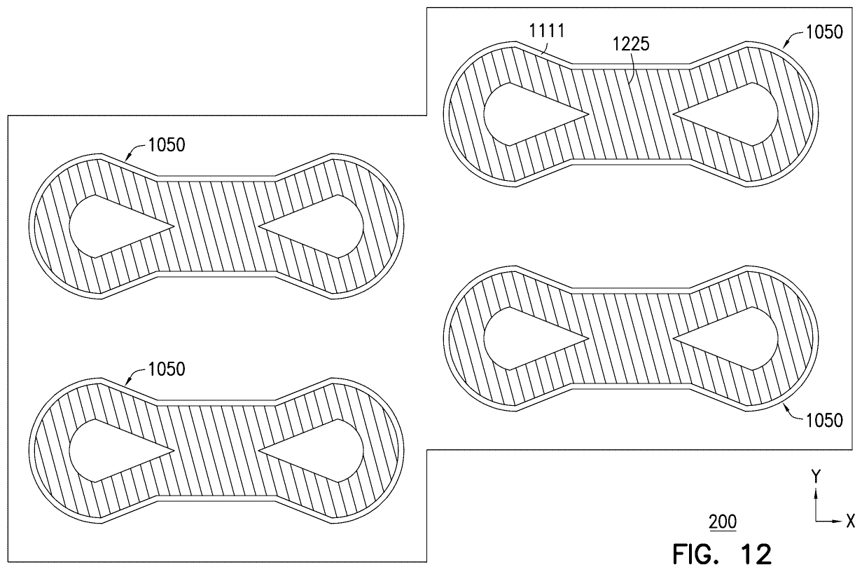

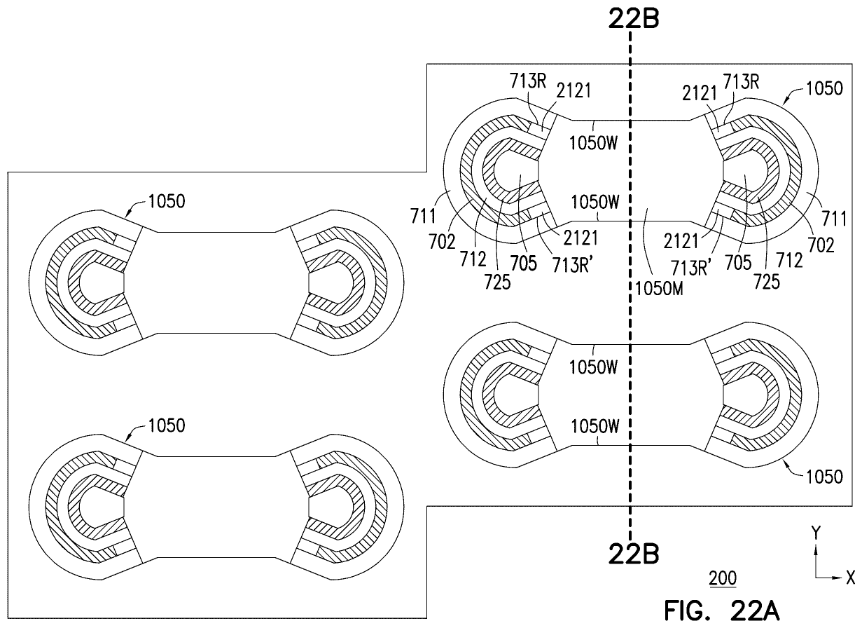

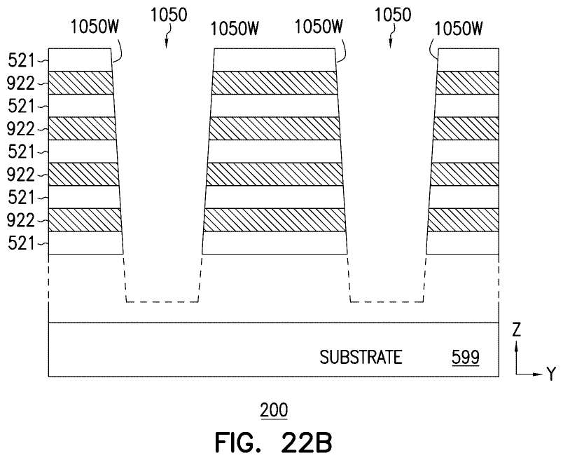

The views of memory device 200 shown in FIG. 10A, FIG. 10B, and FIG. 10C follow the same pattern of views of FIG. 9A, FIG. 9B, and FIG. 9C, respectively. For simplicity, FIG. 11 through FIG. 21 show only the top view (like FIG. 10A) of memory device 200 (omitting the side views). FIG. 22A through FIG. 26B show the top view (like FIG. 10A) and the side view (like FIG. 10B) in the Y-Z direction of memory device 200 (omitting the side view in the X-Z direction).

FIG. 9A, FIG. 9B, and FIG. 9C show memory device 200 after dielectric materials 521 and 922 are formed over substrate 599. Substrate 599 is the same as substrate 599 of FIG. 5A. For simplicity, a portion in dashed line of memory device 200 between substrate 599 and dielectric materials 521 and 922 is omitted. Dielectric materials 521 and 922 can be sequentially formed one material after another, such that dielectric materials 521 and 922 can be interleaved with each other in different levels of memory device 200 as shown in FIG. 9B and FIG. 9C. FIG. 9B and FIG. 9C show different views (in the Y-Z and X-Z directions) of the same dielectric materials 521 and 922.

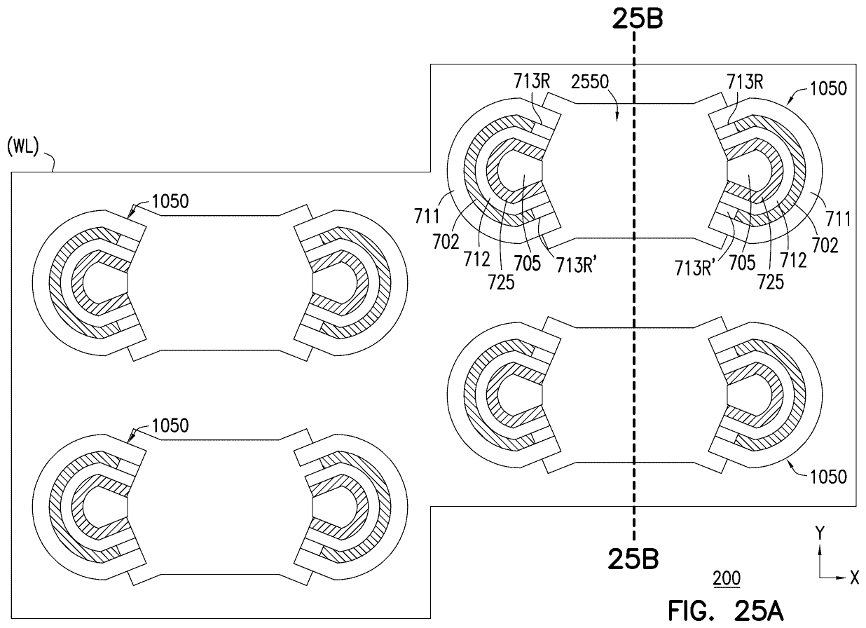

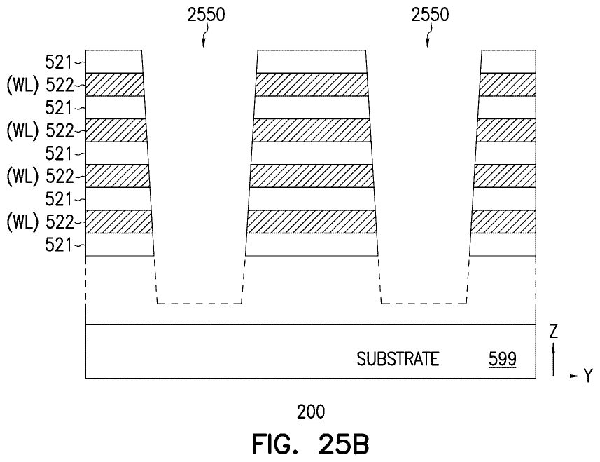

In FIG. 9B and FIG. 9C, dielectric materials 521 can include respective levels of silicon dioxide. Dielectric materials 922 can include respective levels of silicon nitride. In subsequent processes (formed in FIG. 25A and FIG. 25B), dielectric materials (e.g., silicon nitride) 922 can be removed (e.g., exhumed) and replaced with respective levels of conductive material (e.g., tungsten or tungsten-based material or other conductive materials) to form respective control gates (e.g., the control gates associated with signals WL0 through WL3 of FIG. 5A) of memory device 200. In FIG. 9B and FIG. 9C, materials (e.g., silicon dioxide) 521 can correspond to dielectric materials 521 of memory device 200 of FIG. 5A. Dielectric materials 521 can be formed to provide separation (electrical separation) between the control gates (e.g., the control gates associated with signals WL0 through WL3 of FIG. 5A) of memory device 200 that are subsequently formed (formed in FIG. 25A and FIG. 25B).

FIG. 10A, FIG. 10B, and FIG. 10C show memory device 200 after openings (e.g., holes) 1050 are formed dielectric materials 521 and 922. Forming openings 1050 can include removing (e.g., etching) a portion of dielectric materials 521 and 922 at the location of openings 1050. As shown in FIG. 10A, each opening 1050 can include a region 1050L in dielectric materials 521 and 922, a region 1050R in dielectric materials 521 and 922, and a region 1050M between region 1050 l and region 1050R. Regions 1050L, 1050R, and 1050M can have widths W1, W2, and W3, respectively. Each of widths W1, W2, and W3 can be measured in the Y-direction. Widths W1, W2, and W3 can be measured between opposite sidewalls (not labels) in the Y-direction of regions 1050L, 1050R, and 1050M, respectively. For example, width W3 can be measured in the Y-direction perpendicular to a direction (e.g., the X-direction) from region 1050L to region 1050R. Width W3 is less than each of widths W1 and W2.

As shown in FIG. 10A, the shapes of openings 1050 are the same. Thus, for simplicity, elements (e.g., regions 1050L, 1050R, and 1050M, and widths W1, W2, and W3) of only one opening 1050 are labeled. Thus, as shown in FIG. 10A, each opening 1050 can include three open and connected regions: two opposite regions (e.g., regions 1050L and 1050R) and a narrower region (e.g., region 1050M) between the two opposite regions.

FIG. 11 shows memory device 200 after a dielectric material 1111 is formed (e.g., deposited) in openings 1050. Dielectric material 1111 can include silicon dioxide or other dielectric materials. As shown in FIG. 11, dielectric material 1111 can be a relatively thin liner formed on sidewalls of openings 1050.

FIG. 12 shows memory device 200 after a material 1225 is formed (e.g., deposited) in openings 1050 adjacent dielectric material 1111. Material 1225 is different from dielectric material 1111. Material 1225 can include carbon or other materials. In subsequent processes of forming memory device 200, material 1225 is removed from memory device 200. Thus, material 1225 can be called a sacrificial material.

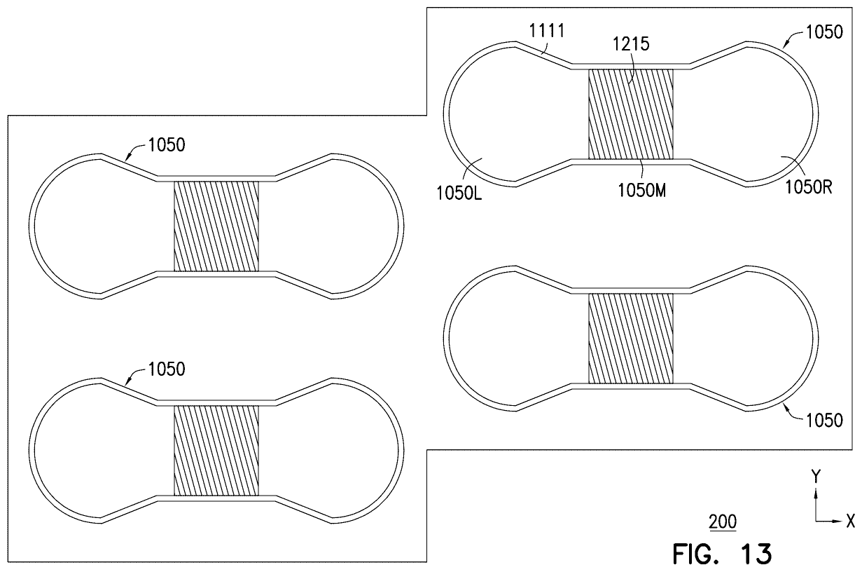

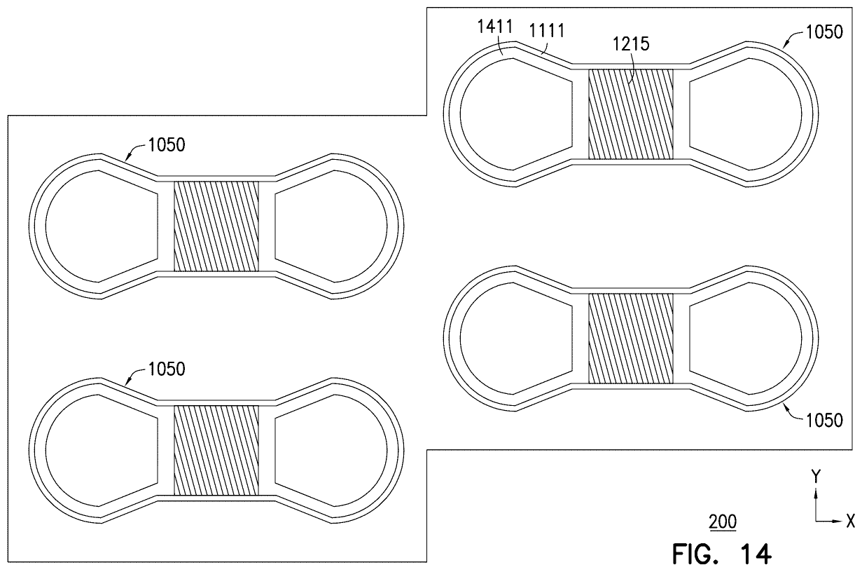

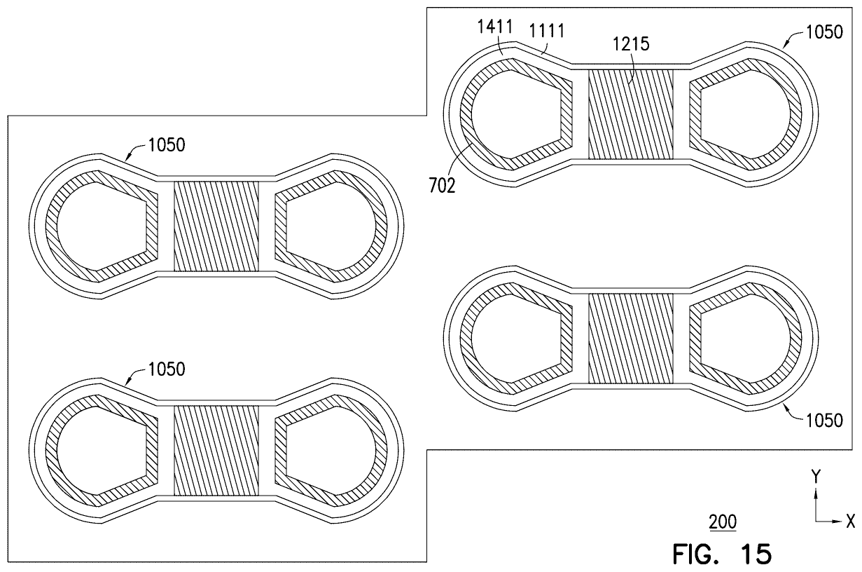

FIG. 13 shows memory device 200 after a portion of material 1225 in regions 1050L and 1050R are removed (e.g., recessed). FIG. 13 shows the remaining portion of material 1225 in region 1050M.

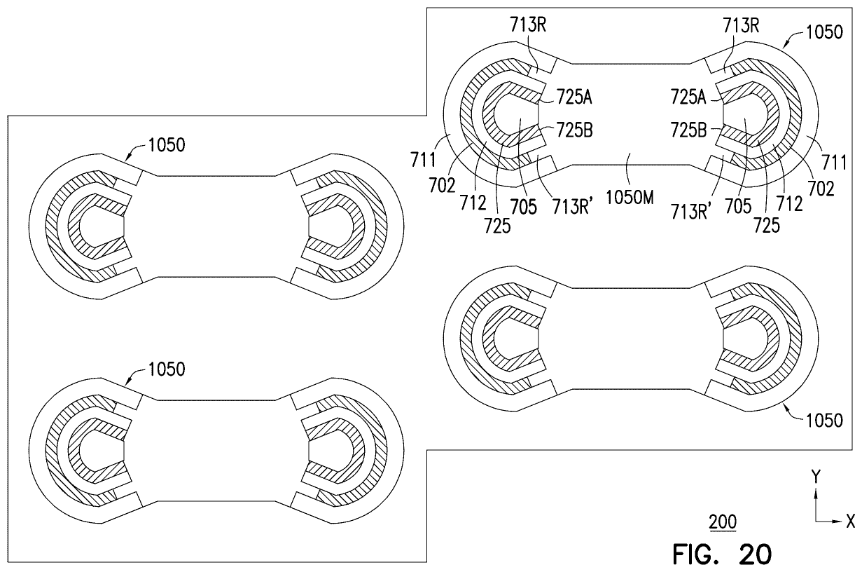

FIG. 14 shows memory device 200 after a dielectric material 1411 is formed (e.g., deposited) in regions 1050L and 1050R of openings 1050. Dielectric material 1411 can be the same as (or different from) dielectric material 1111. For example, dielectric material 1411 can include silicon dioxide or other dielectric materials. In subsequent processes (FIG. 20) of forming memory device 200, dielectric materials 1111 and 1411 in regions 1050L and 1050R can collectively form dielectric material 711 (as also shown in FIG. 7A).

FIG. 15 shows memory device 200 after memory storage material 702 is formed (e.g., deposited) in regions 1050L and 1050R of openings 1050 adjacent dielectric material 1411.

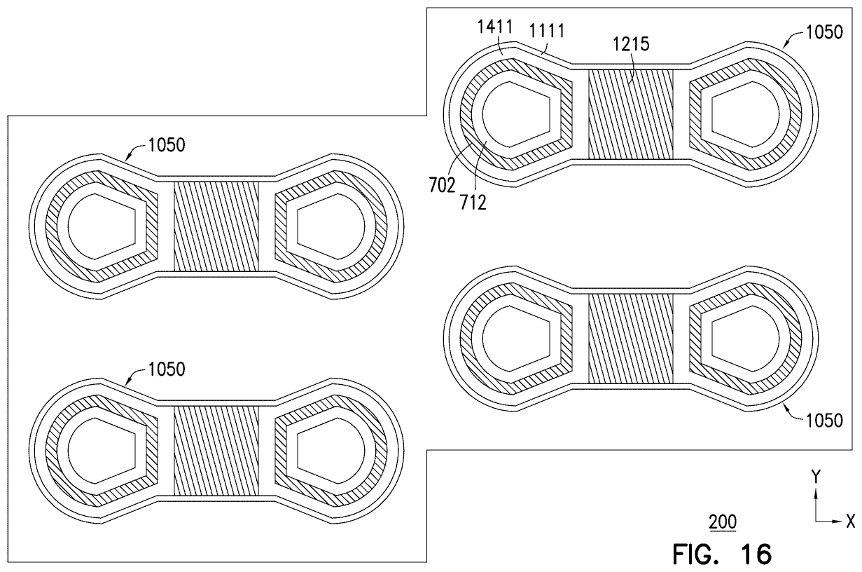

FIG. 16 shows memory device 200 after dielectric material 712 is formed (e.g., deposited) in regions 1050L and 1050R of openings 1050 adjacent memory storage material 702.

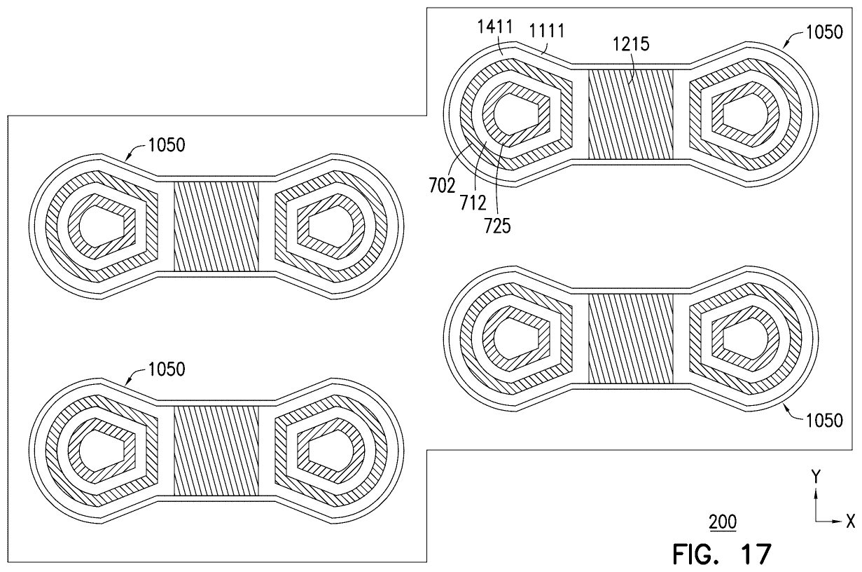

FIG. 17 shows memory device 200 after semiconductor material 725 is formed (e.g., deposited) in regions 1050L and 1050R of openings 1050 adjacent dielectric material 712.

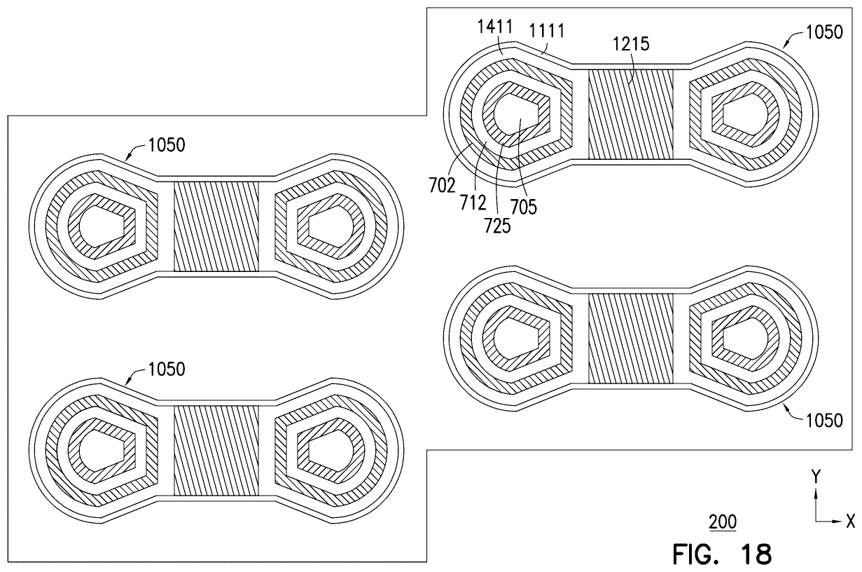

FIG. 18 shows memory device 200 after dielectric material 705 is formed (e.g., filled) in regions 1050L and 1050R of openings 1050 adjacent and surrounded by semiconductor material 725.

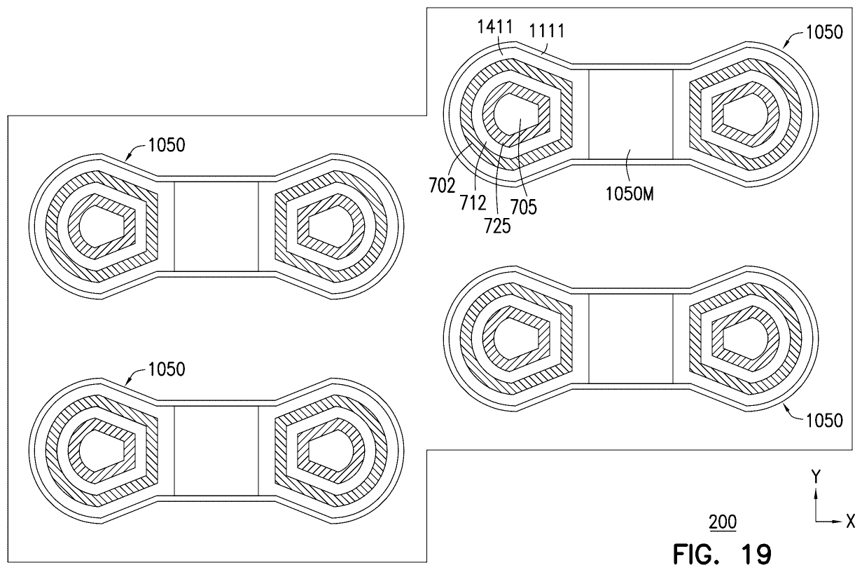

FIG. 19 shows memory device 200 after material 1225 is removed (e.g., exhumed) from region 1050M of openings 1050. Thus, region 1050M in FIG. 19 is an open region (empty region).

FIG. 20 shows memory device 200 after respective portions of dielectric materials 1111, 1141, and 712, memory storage material 702, and semiconductor material 725 adjacent region 1050M are removed (e.g., etched). In FIG. 20, dielectric material 711 is the remaining portions of dielectric materials 1111 and 1141. As shown in FIG. 19, the processes associated with FIG. 19 can form end portions (labeled in FIG. 7B) in each of dielectric materials 711 and 712, memory storage material 702, and semiconductor material 725 at region 1050M.

As shown in FIG. 19, the remaining portion of semiconductor material 725 may not have a round shape (e.g., ring, circular, or oval shape). Semiconductor material 725 has end portions 725A and 725B that are separated from each other at the location of region 1050M. As described above with reference to FIG. 7B, the shape of semiconductor material 725 can reduce or eliminate leakage of current associated with the conductive channel structure (which includes semiconductor material 725) of the pillar (e.g., pillar 550A) of memory device 200.

The processes associated with FIG. 20 can also form recesses (e.g., cavities) 713R and 713R′. As shown in FIG. 20, each of recess 713R and 713R′ is located between (is formed by) a portion of dielectric material 711, a portion of dielectric material 712, and a portion of memory storage material 702.

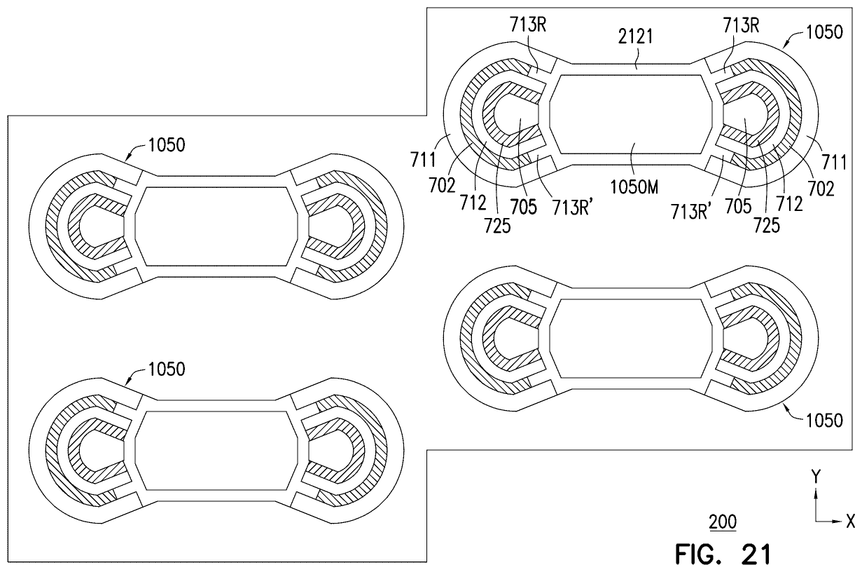

FIG. 21 shows memory device 200 after dielectric material 2121 is formed (e.g., deposited) on sidewalls (not labeled) at region 1050M of openings 1050 and formed adjacent (e.g., adjacent end portions of) dielectric materials 711, 712, and 705, and semiconductor material 725. As shown in FIG. 21, a portion of dielectric material 2121 can be formed (e.g., filled) in recesses 713R and 713R'.

FIG. 22A and FIG. 22B show memory device 200 after a portion of dielectric material 2121 is removed (e.g., using a wet etch process). The remaining portion of dielectric material 2121 is in recesses 713R and 713R'. As shown in FIG. 22A, memory storage material 702 are not exposed at region 1050M of opening 1050 because dielectric material 2121 in recesses 713R and 713R′ is between memory storage material 702 and region 1050M. As shown in FIG. 22B, dielectric materials 521 and 922 are exposed at sidewalls 1050W of openings 1050.

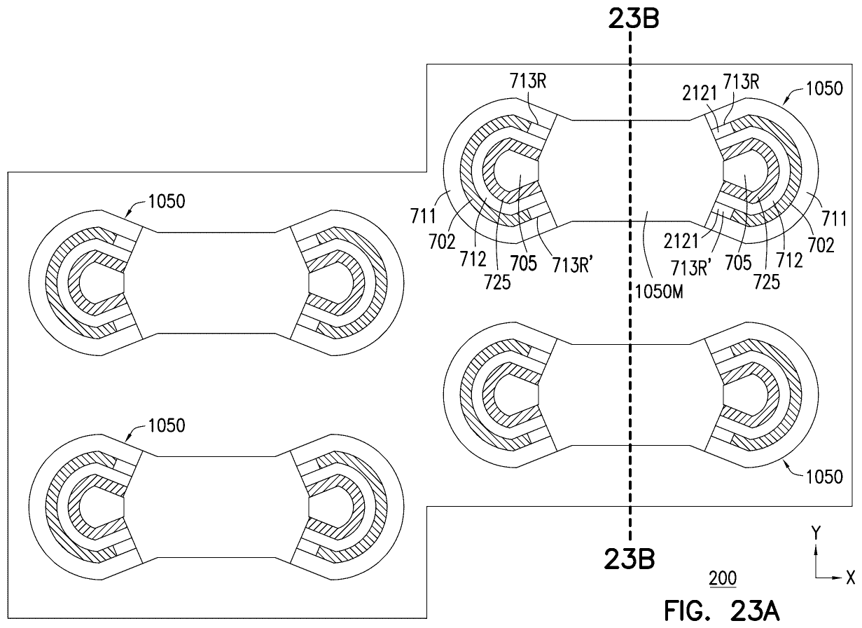

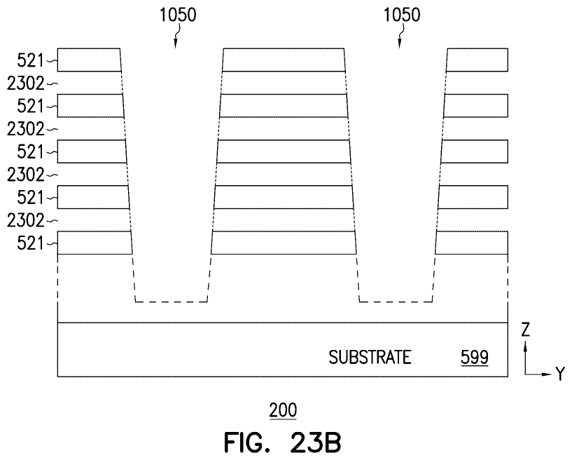

FIG. 23A and FIG. 23B show memory device 200 after dielectric materials 922 (shown in FIG. 22B) are removed (e.g., exhumed) from locations 2302. Locations 2302 in FIG. 23B are voids (empty spaces) that were occupied by dielectric materials 922. In subsequent processes, conductive materials can be formed in locations 2302 to form respective control gates of memory device 200.

In FIG. 23A, memory storage material 702 and dielectric materials 922 (FIG. 22B) may be the same (e.g., silicon nitride). However, as shown in FIG. 23, since dielectric material (e.g., silicon dioxide) 2121 in recesses 713R and 713R′ blocks access (from region 1050M) to memory storage material 702, memory storage material 702 can remain (is not removed) when dielectric materials 922 (FIG. 22B) are removed from locations 2302 (FIG. 23B) during the processes associated with FIG. 23A and FIG. 23B.

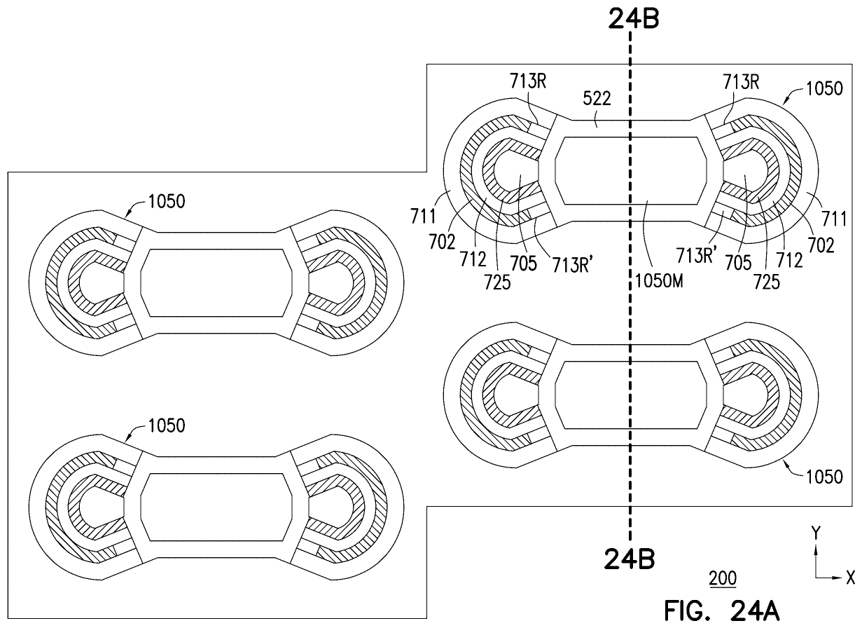

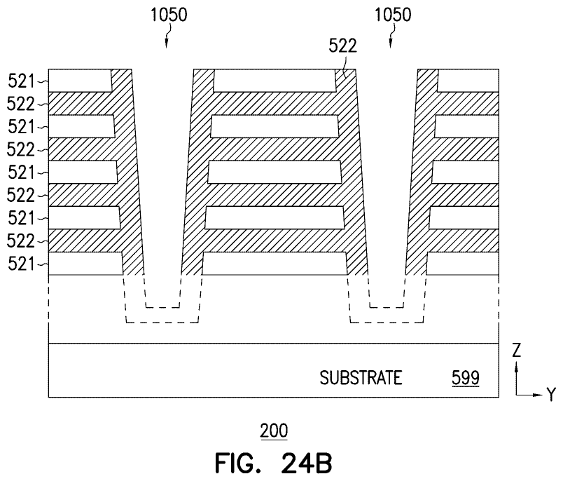

FIG. 24A and FIG. 24B show memory device 200 after conductive material (or conductive materials) 522 is formed (e.g., deposited) in locations 2202 (labeled in FIG. 22B). A portion of conductive material is also formed on sidewall of region 1050M.

FIG. 25A and FIG. 25B show memory device 200 after a portion of conductive material 522 at region 1050M (labeled in FIG. 24A) is removed. In FIG. 25A and FIG. 25B, regions 2550 include an expansion of region 1050M (FIG. 24A) of openings 1050. As shown in FIG. 25B, the processes associated with FIG. 25A and FIG. 25B separated the remaining portions of conductive material 522 from each other in the Z-direction. The separated conductive material 522 form respective control gates (associated with signals WL) of memory device 200.

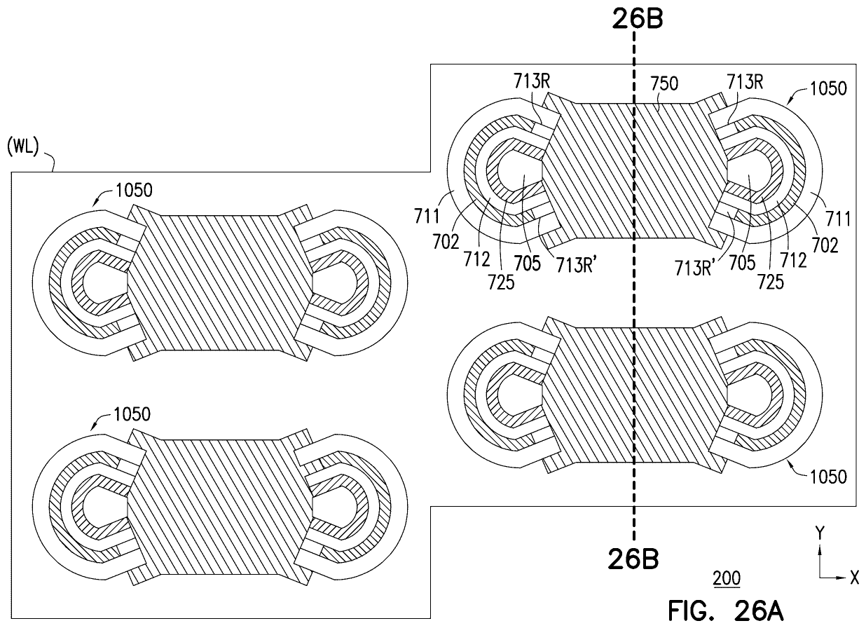

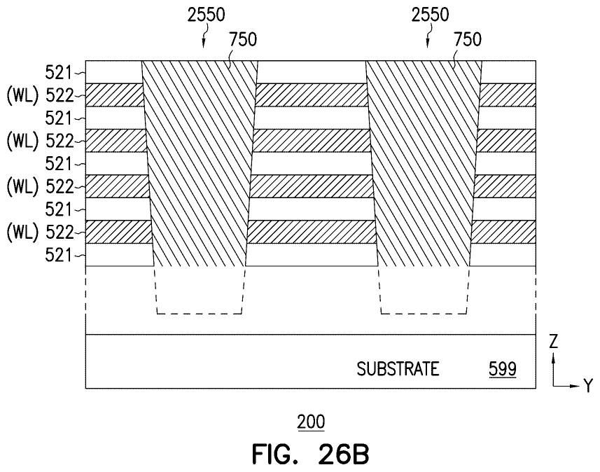

FIG. 26A and FIG. 26B shows memory device 200 after dielectric structure 750 is formed (e.g., deposited) in regions 2550. As shown in FIG. 26B, dielectric structure 750 is adjacent (e.g., adjacent end portions of) dielectric materials 711, 712, and 705, and semiconductor material 725. In an alternative process of forming memory device 200, regions 2550 can be left empty (e.g., not filled with dielectric structure 750). Leaving regions 2550 empty can lower potential electrostatic interference between two memory cells adjacent a respective region 2550.

The processes of forming memory device 200 described above with reference to FIG. 9A through FIG. 26B can include other processes to form a complete memory device (e.g., memory device 200). Such processes are omitted from the above description so as not to obscure the subject matter described herein.

The structure of memory device 200 and the processes described above with reference to FIG. 9A through FIG. 26B provide improvements and benefits over some similar conventional devices. For example, the structure of recess 713R and 713R′ (e.g., FIG. 22A) allow other processes (the processes associated with FIG. 22A and FIG. 22B) to be performed without impacting (e.g., without eroding) the structure of memory storage material 702. This allow memory storage material 702 to provide proper memory storage function. In another example, the structure of semiconductor material 725 (e.g., FIG. 7C) having separate portions (e.g., end portions 725A and 725B) can prevent or reduce charge leakage in respective memory cells of the pillar (e.g., pillar 550A or 550B). This can lead to improved reliability of performance of memory device 200. In another example, forming dielectric structure 750 as described above can avoid alternative processes (dry etch or other processes) that may have a relatively higher cost than the processes described above. Further, the structures of the memory cell pillars of memory device 200 can lead to a relatively higher cell density (in the X-Y direction).

The illustrations of apparatuses (e.g., memory devices 100 and 200) and methods (e.g., method of forming memory device 200) are intended to provide a general understanding of the structure of various embodiments and are not intended to provide a complete description of all the elements and features of apparatuses that might make use of the structures described herein. An apparatus herein refers to, for example, either a device (e.g., any of memory devices 100 and 200) or a system (e.g., a computer, a cellular phone, or other electronic systems) that includes a device such as any of memory devices 100 and 200.

Any of the components described above with reference to FIG. 1 through FIG. 26B can be implemented in a number of ways, including simulation via software. Thus, apparatuses, e.g., memory devices 100 and 200 or part of each of these memory devices described above, may all be characterized as “modules” (or “module”) herein. Such modules may include hardware circuitry, single-and/or multi-processor circuits, memory circuits, software program modules and objects and/or firmware, and combinations thereof, as desired and/or as appropriate for particular implementations of various embodiments. For example, such modules may be included in a system operation simulation package, such as a software electrical signal simulation package, a power usage and ranges simulation package, a capacitance-inductance simulation package, a power/heat dissipation simulation package, a signal transmission-reception simulation package, and/or a combination of software and hardware used to operate or simulate the operation of various potential embodiments.

Memory devices 100 and 200 may be included in apparatuses (e.g., electronic circuitry) such as high-speed computers, communication and signal processing circuitry, single-or multi-processor modules, single or multiple embedded processors, multicore processors, message information switches, and application-specific modules, including multilayer, multichip modules. Such apparatuses may further be included as subcomponents within a variety of other apparatuses (e.g., electronic systems), such as televisions, cellular telephones, personal computers (e.g., laptop computers, desktop computers, handheld computers, tablet computers, etc.), workstations, radios, video players, audio players (e.g., MP3 [Motion Picture Experts Group, Audio Layer 3] players), vehicles, medical devices (e.g., heart monitor, blood pressure monitor, etc.), set top boxes, and others.

The embodiments described above with reference to FIG. 1 through FIG. 26B include apparatuses and methods of forming the apparatuses. One of the apparatuses includes a memory device. The memory device includes levels of conductive materials interleaved with levels of dielectric materials and a memory cell pillar extending through the levels of conductive materials and the levels of dielectric materials. The memory cell pillar includes: a first dielectric material; a second dielectric material; a memory storage material between the first dielectric material and the second dielectric material; a semiconductor material adjacent the second dielectric material; a recess between a portion of the first dielectric material, a portion of the second dielectric material, and a portion of the memory storage material; and a third dielectric material filled in the recess. Other embodiments including additional apparatuses and methods are described.

In the detailed description and the claims, the term “on” used with respect to two or more elements (e.g., materials), one “on” the other, means at least some contact between the elements (e.g., between the materials). The term “over” means the elements (e.g., materials) are in close proximity, but possibly with one or more additional intervening elements (e.g., materials) such that contact is possible but not required. Neither “on” nor “over” implies any directionality as used herein unless stated as such.

In the detailed description and the claims, the terms “first”, “second”, and “third,” etc. are used merely as labels, and are not intended to impose numerical requirements on their objects.

In the detailed description and the claims, a list of items joined by the term “at least one of” can mean any combination of the listed items. For example, if items A and B are listed, then the phrase “at least one of A and B” means A only; B only; or A and B. In another example, if items A, B, and C are listed, then the phrase “at least one of A, B and C” means A only; B only; C only; A and B (excluding C); A and C (excluding B); B and C (excluding A); or all of A, B, and C. Item A can include a single element or multiple elements. Item B can include a single element or multiple elements. Item C can include a single element or multiple elements.

In the detailed description and the claims, a list of items joined by the term “one of” can mean only one of the list items. For example, if items A and B are listed, then the phrase “one of A and B” means A only (excluding B), or B only (excluding A). In another example, if items A, B, and C are listed, then the phrase “one of A, B and C” means A only; B only; or C only. Item A can include a single element or multiple elements. Item B can include a single element or multiple elements. Item C can include a single element or multiple elements.

The above description and the drawings illustrate some embodiments of the inventive subject matter to enable those skilled in the art to practice the embodiments of the inventive subject matter. Other embodiments may incorporate structural, logical, electrical, process, and other changes. Examples merely typify possible variations. Portions and features of some embodiments may be included in, or substituted for, those of others. Many other embodiments will be apparent to those of skill in the art upon reading and understanding the above description.

What is claimed is:

1. An apparatus comprising:
levels of conductive materials interleaved with levels of dielectric materials;
a memory cell pillar extending through the levels of conductive materials and the levels of dielectric materials, the memory cell pillar including:
a first dielectric material;
a second dielectric material;
a memory storage material between the first dielectric material and the second dielectric material;
a semiconductor material adjacent the second dielectric material;
a recess between a portion of the first dielectric material, a portion of the second dielectric material, and a portion of the memory storage material; and
a third dielectric material filled in the recess.

2. The apparatus of claim 1, wherein the memory storage material includes a first end portion, a second end portion, and a third portion between the first end portion and the second end portion, and wherein the third portion has a curved shape.

3. The apparatus of claim 1, wherein the semiconductor material includes a first end portion, and a second end portion, and a third portion between the first end portion and the second end portion, and wherein the third portion has a curved shape.

4. The apparatus of claim 1, wherein each of first dielectric material and the second dielectric material, includes a first end portion, and a second end portion, and a third portion between the first end portion and the second end portion, and wherein the third portion has a curved shape.

5. The apparatus of claim 1, further comprising:
an additional memory cell pillar, the additional memory cell pillar including:
a first additional dielectric material;
a second additional dielectric material;
an additional memory storage material between the first additional dielectric material and the second additional dielectric material;
an additional semiconductor material adjacent the second additional dielectric material;
an additional recess between a portion of the first additional dielectric material, a portion of the second additional dielectric material, and a portion of the additional memory storage material; and
a dielectric structure between the memory cell pillar and the additional memory cell pillar, wherein the dielectric structure is adjacent the semiconductor material and the additional semiconductor material.

6. The apparatus of claim 5, wherein the dielectric structure is adjacent the first dielectric material, the first additional dielectric material, the second dielectric material, and the second additional dielectric material.

7. The apparatus of claim 5, wherein:
the memory cell pillar includes a first curved portion and a first tapered portion;
the additional memory cell pillar includes a second curved portion and a second tapered portion; and
the dielectric structure is adjacent and between the first tapered portion and the second tapered portion.

8. The apparatus of claim 1, wherein the memory storage material includes silicon nitride.

9. The apparatus of claim 8, wherein each of the first dielectric material and the second dielectric material includes silicon dioxide.

10. An apparatus comprising:
levels of conductive materials interleaved with levels of dielectric materials;
a first memory cell pillar extending through the levels of conductive materials and the levels of dielectric materials;
a second memory cell pillar extending through the levels of conductive materials and the levels of dielectric materials;
a third memory cell pillar adjacent the first memory cell pillar and extending through the levels of conductive materials and the levels of dielectric materials;
a fourth memory cell pillar adjacent the second memory cell pillar and extending through the levels of conductive materials and the levels of dielectric materials;
a first dielectric structure located between the first memory cell pillar and the second memory cell pillar; and
a second dielectric structure separated from the first dielectric structure and located between the third memory cell pillar and the fourth memory cell pillar.

11. The apparatus of claim 10, wherein each of the first memory cell pillar and second memory cell pillar includes:
a first dielectric material;
a second dielectric material;
a memory storage material between the first dielectric material and the second dielectric material; and
a semiconductor material adjacent the second dielectric material, wherein the first dielectric structure is adjacent the first dielectric material, the second dielectric material, and the semiconductor material of each of the first memory cell pillar and the second memory cell pillar.

12. The apparatus of claim 11, wherein each of the third memory cell pillar and the fourth memory cell pillar includes:
a first additional dielectric material;
a second additional dielectric material;
an additional memory storage material between the first additional dielectric material and the second additional dielectric material; and
an additional semiconductor material adjacent the second additional dielectric material, wherein the second dielectric structure is adjacent the first additional dielectric material, the second additional dielectric material, and the additional semiconductor material of each of the third memory cell pillar and the fourth memory cell pillar.

13. The apparatus of claim 10, wherein one of the levels of conductive materials includes:
a first concave portion adjacent a portion of the first memory cell pillar;
a second concave portion adjacent a portion of the second memory cell pillar;
a third concave portion adjacent a portion of the third memory cell pillar; and
a fourth concave portion adjacent a portion of the fourth memory cell pillar.

14. The apparatus of claim 10, wherein each of the first dielectric material, the second dielectric material, and the semiconductor material of each of the first memory cell pillar and the second memory cell pillar includes a first end portion, a second end portion, and a third portion between the first end portion and the second end portion, and wherein the third portion has a curved shape.

15. The apparatus of claim 12, wherein each of the first additional dielectric material, the second additional dielectric material, and the additional semiconductor material of each of the third memory cell pillar and the fourth memory cell pillar includes a first additional end portion, a second additional end portion, and a third additional portion between the first additional end portion and the second additional end portion, and wherein the third additional portion has a curved shape.

16. The apparatus of claim 10, wherein each of the fist memory cell pillar, the second memory cell pillar, the third memory cell pillar, and the fourth memory cell pillar has partial-cylindrical shape.

17. A method comprising:
forming levels of first materials interleaved levels of second materials;
forming an opening in the levels of first materials and the levels of second materials, such that the opening includes a first region in the levels of first materials and the levels of second materials, a second region the levels of first materials and the levels of second materials, and a third region in the levels of first materials and the levels of second materials, wherein the third region is between the first region and the second region;
forming a first memory cell pillar in the first region;
forming a second memory cell pillar adjacent the first memory cell pillar in the second region; and
forming a dielectric structure in the third region.

18. The method of claim 17, wherein the third region has a width in a direction perpendicular to a direction from the first region to the second region, and the width is less than a width of each of the first region and the second region.

19. The method of claim 17, further comprising:
forming an additional opening in the levels of first materials and the levels of second materials, such that the additional opening includes:
a first additional region in the levels of first materials and the levels of second materials;
a second additional region the levels of first materials and the levels of second materials; and
a third additional region in the levels of first materials and the levels of second materials, wherein the third additional region is between the first additional region and the second additional region;
forming a third memory cell pillar in the first additional region and adjacent the first memory cell pillar;
forming a fourth memory cell pillar in the second additional region and adjacent the second memory cell pillar; and
forming an additional dielectric structure in the third additional region, wherein the additional dielectric structure is separated from the dielectric structure.

20. The method of claim 17, wherein forming each of the first memory cell pillar and the second memory cell pillar includes:
forming a first dielectric material;
forming a memory storage material adjacent the first dielectric material; and
forming a second dielectric material adjacent the memory storage material.
